(19) United States
(12) Patent Application Publication
(10) Pub. No.: US 2025/0374656 A1
(43) Pub. Date: Dec. 4, 2025

(54) SEMICONDUCTOR PROCESSING INTEGRATION FOR BIPOLAR JUNCTION TRANSISTOR (BJT)

(71) Applicant: TEXAS INSTRUMENTS INCORPORATED, Dallas, TX (US)

(72) Inventors: Giulio Albini, Draper, UT (US); Jonathan Lane, Sandy, UT (US); Robert Cassel, Lehi, UT (US)

(21) Appl. No.: 18/679,642

(22) Filed: May 31, 2024

(51) Int. Cl. H01L 27/06; H01L 29/08; H01L 29/10; H01L 29/66; H01L 29/737

(52) U.S. Cl. CPC H10D 84/401; H10D 10/021; H10D 10/821; H10D 62/138; H10D 62/177

(57) ABSTRACT

The present disclosure generally relates to semiconductor processing integration for a bipolar junction transistor (BJT). In an example, a semiconductor device includes a semiconductor substrate, a bipolar junction transistor (BJT), a field effect transistor (FET), and a composite structure. The semiconductor substrate includes a BJT region, a complementary FET (CFET) region, and a transition region between the BJT region and the CFET region. The BJT is on the semiconductor substrate in the BJT region. The FET is on the semiconductor substrate in the CFET region. The composite structure is on the semiconductor substrate in the transition region. The composite structure includes a dielectric material. The dielectric material has a sidewall proximate and facing the CFET region and has a top surface that forms at least a portion of an upper surface of the composite structure.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, a bipolar junction transistor (BJT), a field effect transistor (FET), and a composite structure. The semiconductor substrate includes a BJT region, a complementary FET (CFET) region, and a transition region between the BJT region and the CFET region. The BJT is on the semiconductor substrate in the BJT region. The FET is on the semiconductor substrate in the CFET region. The composite structure is on the semiconductor substrate in the transition region. The composite structure includes a dielectric material. The dielectric material has a sidewall proximate and facing the CFET region and has a top surface that forms at least a portion of an upper surface of the composite structure.

Another example is a method. A gate layer is formed over a semiconductor substrate in a BJT region, a transition region, and a CFET region. The transition region is between the BJT region and the CFET region. The gate layer is patterned into a gate electrode of a FET in the CFET region. After patterning the gate layer into the gate electrode, a collector layer is formed on an upper surface of the semiconductor substrate in the BJT region. A base layer is formed on the collector layer. An emitter layer is formed on the base layer.

A further example is a method. A gate layer is formed over a semiconductor substrate in a BJT region and a CFET region. The gate layer is patterned in the CFET region into a gate electrode of a FET in the CFET region. A fill material is formed in the CFET region along a side of the gate electrode. A collector layer is formed on the semiconductor substrate and in the BJT region. A material of a base layer is formed over the collector layer and over the fill material. A material of an emitter layer is formed over the base layer. The material of the emitter layer is patterned into the emitter layer in the BJT region. The material of the base layer is patterned into the base layer in the BJT region.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1A and 1B through FIGS. 35A and 35B are respective cross-sectional views of a semiconductor device in intermediate stages of manufacturing according to some examples.

FIGS. 36A and 36B through FIGS. 42A and 42B are respective cross-sectional views of a semiconductor device in intermediate stages of manufacturing according to some examples.

FIG. 43 is a layout view of overlaid components of a bipolar junction transistor (BJT) according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing integration for a bipolar junction transistor (BJT). Some examples include a semiconductor device including a BJT. A semiconductor substrate includes a BJT region, a complementary field effect transistor (CFET) region, and a transition region between the BJT region and the CFET region. A BJT is on the semiconductor substrate in the BJT region, and a field effect transistor (FET) is on the semiconductor substrate in the CFET region. A composite structure is on the semiconductor substrate in the transition region. The composite structure includes a dielectric material that has a sidewall proximate and facing the CFET region and has a top surface that forms at least a portion of a top surface of the composite structure. Methods of fabricating such a semiconductor device are described. Generally, such methods of fabrication may avoid performing some higher temperature processing after doped layers of a BJT have been formed, which may permit outdiffusion and/or outgassing of dopants from those doped layers to be reduced. Other benefits and advantages may be achieved.

Various examples are described subsequently. Although the specific examples may illustrate various aspects of the above generally described features, examples may incorporate any combination of the above generally described features (which are described in more detail in examples below).

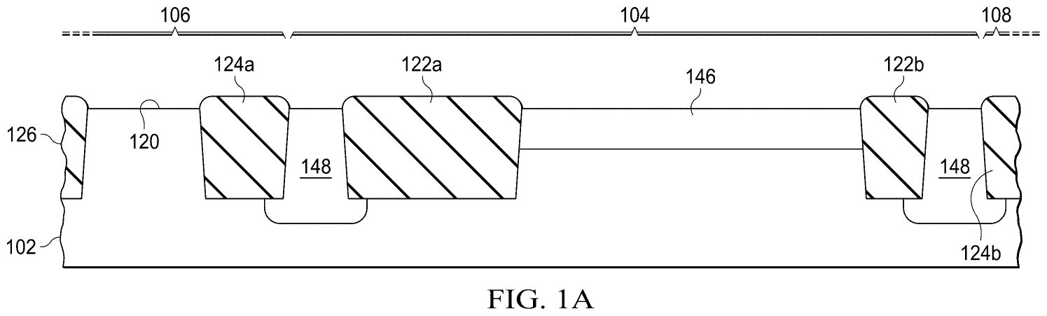

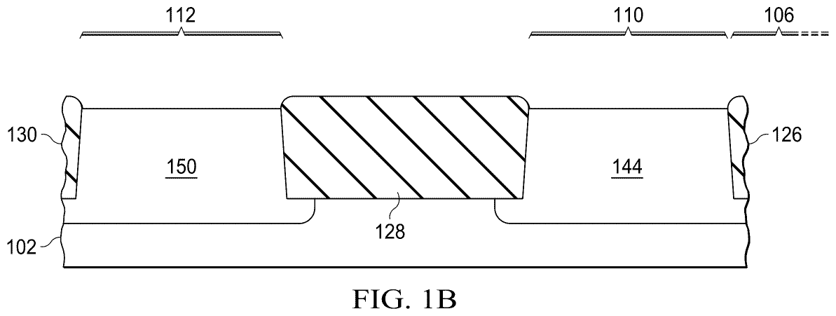

FIGS. 1A and 1B through FIGS. 35A and 35B are respective cross-sectional views of a semiconductor device in intermediate stages of manufacturing according to some examples. Referring to FIGS. 1A and 1B, a semiconductor substrate 102 is provided. The semiconductor substrate 102 includes a BJT region 104, a first transition region 106, a second transition region 108, a p-type FET (pFET) region 110, and an n-type FET (nFET) region 112. Together, the pFET region 110 and the nFET region 112 are included in a complementary field effect transistor (CFET) region.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as a BJT, a pFET, and an nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 122 (including a first portion 122a and a second portion 122b), 124 (including a first portion 124a and a second portion 124b), 126, 128, 130 are formed on the semiconductor substrate 102. In the illustrated example, the isolation structures 122-130 are shallow trench isolation structures (STIs) extending from the upper surface 120 of the semiconductor substrate 102 into the semiconductor substrate 102. As illustrated, the isolation structures 122-130 are also raised above the upper surface 120 of the semiconductor substrate 102, and in other examples, the isolation structures 122-130 may have respective upper surfaces co-planar with and/or below the upper surface 120 of the semiconductor substrate 102. The isolation structures 122-130 may include, for example, a liner layer, such as including silicon oxide or silicon nitride, conformally along surfaces of a respective trench in the semiconductor substrate 102 and a fill isolation material, such as silicon oxide, over and on the liner layer.

The isolation structures 122-130, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 122-130 may be field oxide structures, such as local oxidation of silicon (LOCOS) structures, at the upper surface 120 of the semiconductor substrate 102, which may be formed using a LOCOS process.

The isolation structure 122 laterally defines an active area of the upper surface 120 of the semiconductor substrate 102 on which the BJT is to be formed. The isolation structure 122 laterally encircles or encompasses the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 122a of the isolation structure 122. Further, the isolation structure 124 defines lateral boundaries of the BJT region 104. The isolation structure 124 laterally encircles or encompasses the isolation structure 122 with a doped isolation or guarding well therebetween, as described subsequently.

The isolation structures 126, 128 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 128, 130 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the isolation structure 126 and the first portion 124a of the isolation structure 124. As illustrated, a portion of the upper surface 120 of the semiconductor substrate 102 is between the first portion 124a of the isolation structure 124 and the isolation structure 126 in the first transition region 106. In other examples, the first transition region 106 may have an isolation structure laterally throughout the first transition region 106. The second transition region 108 is defined from a lateral boundary of the BJT region 104 to a nearest lateral boundary of another region (not illustrated). The second transition region 108 includes the second portion 124b of the isolation structure 124. The second transition region 108 may be formed and/or structured like the first transition region 106.

An n-type doped well 144 is formed in the semiconductor substrate 102 in the pFET region 110. The n-type doped well 144 may be formed by masking (e.g., by a photoresist using photolithography) areas of the semiconductor substrate 102 where an n-type doped well is not to be formed and implanting n-type dopants into the semiconductor substrate 102. The n-type doped well 144 extends from the upper surface 120 of the semiconductor substrate 102 into a depth in the semiconductor substrate 102 and is in the pFET region 110 laterally between the isolation structures 126, 128. A concentration of the n-type dopant of the n-type doped well 144 is greater than a concentration of the p-type dopant of the p-type doped semiconductor substrate 102. In some examples, the n-type doped well 144 is doped with an n-type dopant (e.g., phosphorus (P) or arsenic (As)) with a concentration in a range from 1×10¹⁵ cm⁻³ to 1×10¹⁷ cm⁻³. Another dopant and/or other doping concentrations may be implemented.

An n-type doped sub-collector diffusion region 146 is formed in the semiconductor substrate 102 in the BJT region 104 and laterally between the portions 122a, 122b of the isolation structure 122. The n-type doped sub-collector diffusion region 146 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 146 extends from the upper surface 120 of the semiconductor substrate 102 into a depth in the semiconductor substrate 102 and is in the BJT region 104 laterally between the portions 122a, 122b of the isolation structure 122. A concentration of the n-type doped sub-collector diffusion region 146 is greater than a concentration of the p-type dopant of the semiconductor substrate 102. In some examples, the n-type doped sub-collector diffusion region 146 is doped with an n-type dopant with a concentration in a range from 1×10¹⁸ cm⁻³ to 1×10²⁰ cm⁻³. Another dopant and/or other doping concentrations may be implemented.

P-type doped wells 148, 150 are formed in the semiconductor substrate 102. The p-type doped wells 148, 150 may be formed by masking (e.g., by a photoresist using photolithography) areas of the semiconductor substrate 102 where a p-type doped well is not to be formed and implanting p-type dopants into the semiconductor substrate 102. The p-type doped well 148 extends from the upper surface 120 of the semiconductor substrate 102 into a depth in the semiconductor substrate 102 and is in the BJT region 104 laterally between the isolation structures 122, 124. The p-type doped well 148 is an isolation ring or guardring laterally encircling or encompassing the active area in which the BJT is to be formed. The p-type doped well 150 extends from the upper surface 120 of the semiconductor substrate 102 into a depth in the semiconductor substrate 102 and is in the nFET region 112 laterally between the isolation structures 128, 130. A concentration of the p-type dopant of the p-type doped wells 148, 150 is greater than a concentration of the p-type dopant of the p-type doped semiconductor substrate 102. In some examples, the p-type doped wells 148, 150 are doped with a p-type dopant with a concentration in a range from 1×10¹⁵ cm⁻³ to 1×10¹⁷ cm⁻³. Another dopant and/or other doping concentrations may be implemented.

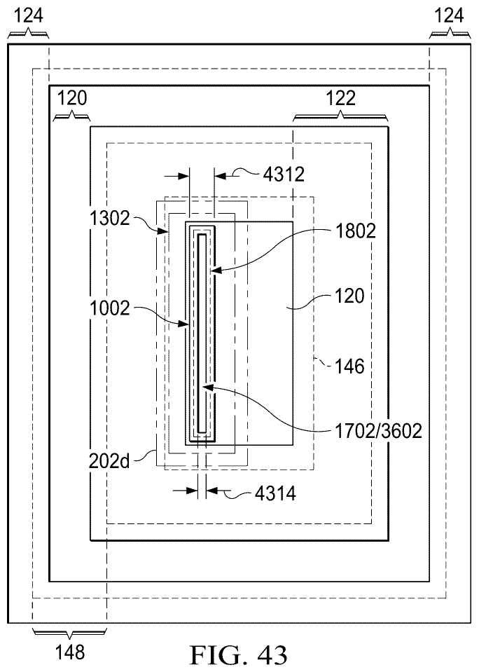

Referring to FIG. 43, the n-type doped sub-collector diffusion region 146 and the p-type doped well 148 are shown (e.g., by dashed line boundaries) in a layout view of the BJT region 104 and neighboring portions of the transition regions 106, 108. Additionally, the isolation structures 122, 124 are shown (e.g., by solid line boundaries) with the upper surface 120 of the semiconductor substrate 102 shown between the isolation structures 122, 124, as well as within the isolation structure 122.

Although the semiconductor substrate 102, n-type doped well 144, n-type doped sub-collector diffusion region 146, and p-type doped wells 148, 150 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

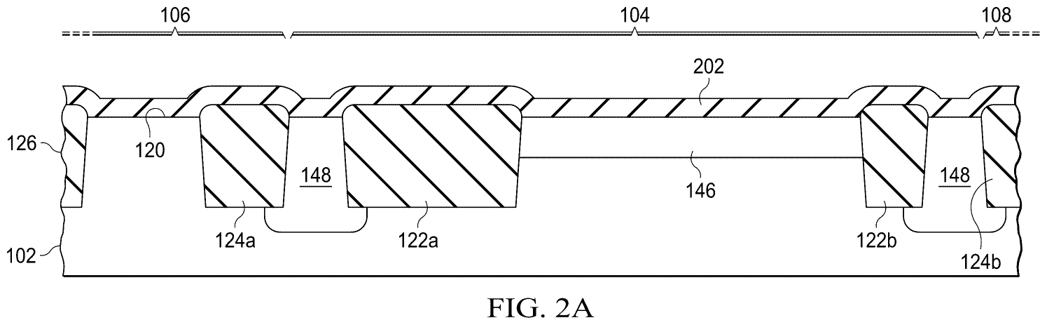

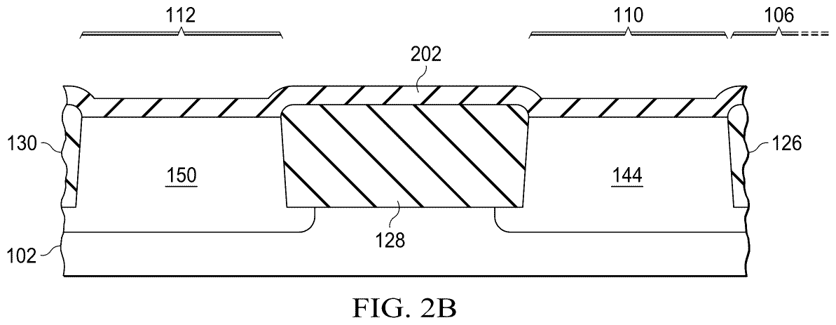

Referring to FIGS. 2A and 2B, a pedestal dielectric layer 202 is formed over the semiconductor substrate 102. The pedestal dielectric layer 202 is conformally deposited over the upper surface 120 of the semiconductor substrate 102 and the isolation structures 122-130. In some examples, the pedestal dielectric layer 202 is silicon oxide (e.g., a tetraethyl orthosilicate (TEOS) oxide) deposited by CVD, although other dielectric materials and/or other deposition processes may be used in other examples.

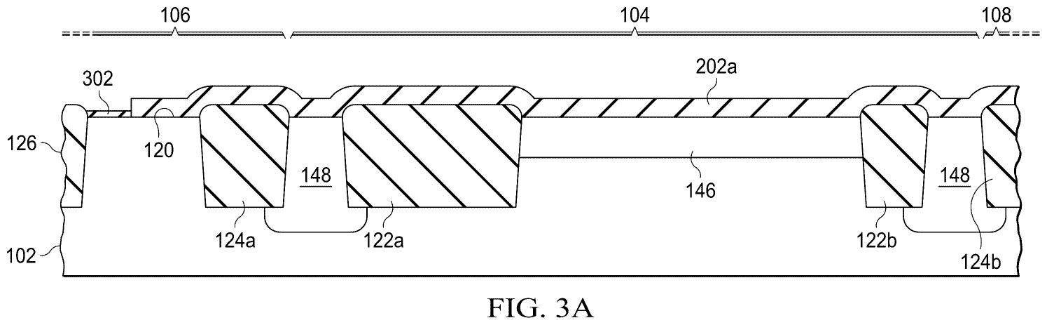

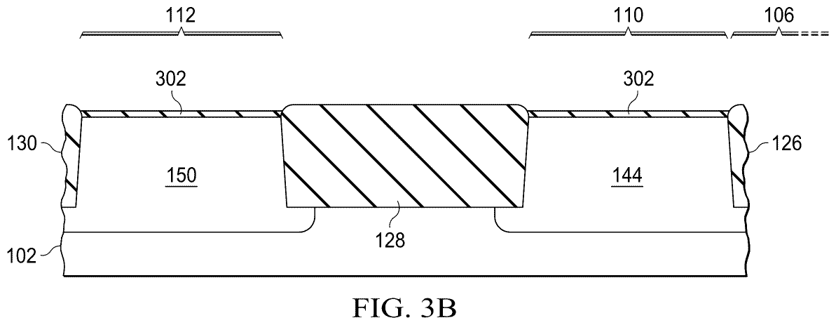

Referring to FIGS. 3A and 3B, the pedestal dielectric layer 202 is removed from the upper surface 120 of the semiconductor substrate 102 in the pFET region 110, the nFET region 112, and, partially, the first transition region 106 such that pedestal dielectric layer 202a remains in the BJT region 104 and at least partially the transition regions 106, 108. In the illustrated example, the portion of the pedestal dielectric layer 202 is removed using appropriate photolithography and etch (e.g., RIE) processes.

Gate dielectric layers 302 are formed on or over the upper surface 120 of the semiconductor substrate 102 in the pFET region 110, the nFET region 112, and the first transition region 106. In some examples, the gate dielectric layers 302 may be silicon oxide formed using oxidation, such as by in situ steam generation (ISSG) oxidation or another oxidation process. In other examples, another dielectric material and/or another deposition process may be used to form the gate dielectric layers 302. In some examples, different gate dielectric layers and/or gate dielectric layers with different thicknesses may be formed in different regions, such as to form pFETs and/or nFETs rated for different operating voltages (e.g., in high voltage applications, medium voltage applications, or low voltage applications). In such examples, iterative processes for removing different portions of the pedestal dielectric layer 202 and oxidizing the upper surface 120 of the semiconductor substrate 102 may be performed, such as described in U.S. patent application Ser. No. 18/520,527, entitled “SEMICONDUCTOR PROCESSING INTEGRATION FOR BIPOLAR JUNCTION TRANSISTOR (BJT)”, filed on Nov. 27, 2023, the entirety of which is incorporated herein by reference.

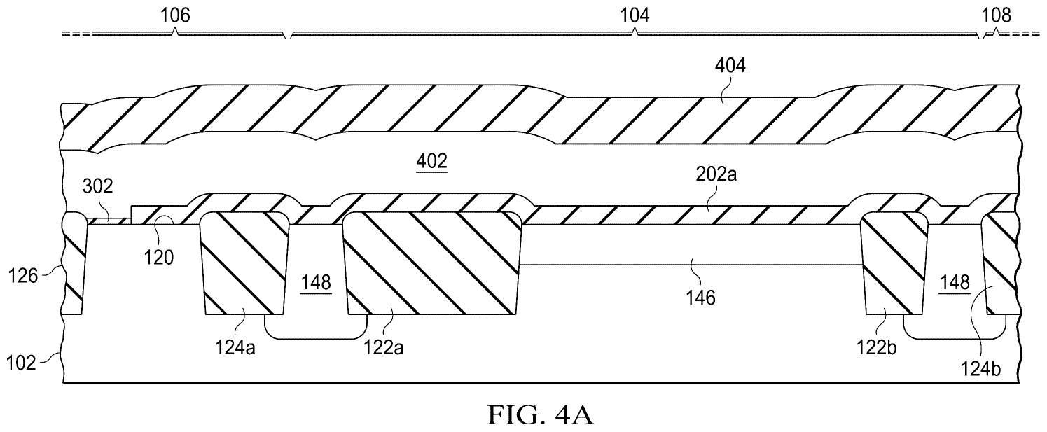

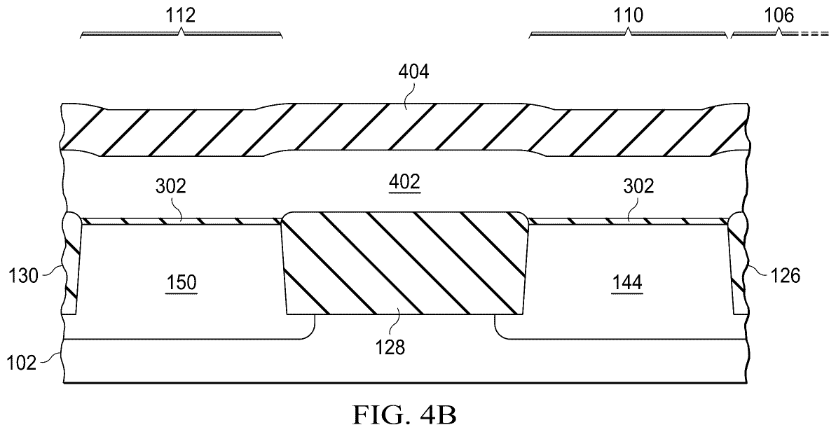

Referring to FIGS. 4A and 4B, a gate layer 402 is formed over the semiconductor substrate 102, and a hardmask layer 404 is formed over the gate layer 402. The gate layer 402 is formed over the gate dielectric layers 302 and the pedestal dielectric layer 202a. In some examples, the gate layer 402 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. For example, the gate layer 402 may be in situ doped during deposition with a p-type dopant, and after deposition, a portion of the gate layer 402 may be implanted with an n-type dopant to a greater concentration than the p-type dopant while another portion of the gate layer 402 is masked (e.g., by a photoresist formed by photolithography). In some examples, the gate layer 402 in the BJT region 104, transition regions 106, 108, and pFET region 110 is polysilicon doped with a p-type dopant with a concentration in a range from 1×10¹⁹ cm⁻³ to 1×10²¹ cm⁻³ after deposition and/or implantation, and the gate layer 402 in the nFET region 112 is polysilicon doped with an n-type dopant with a concentration in a range from 5×10¹⁹ cm⁻³ to 5×10²¹ cm⁻³ after implantation. Other materials (e.g., conductive material) may be implemented as the gate layer 402, which may be formed by any deposition process. In some examples, the hardmask layer 404 is silicon nitride deposited by CVD, although other dielectric materials and/or other deposition processes may be used in other examples.

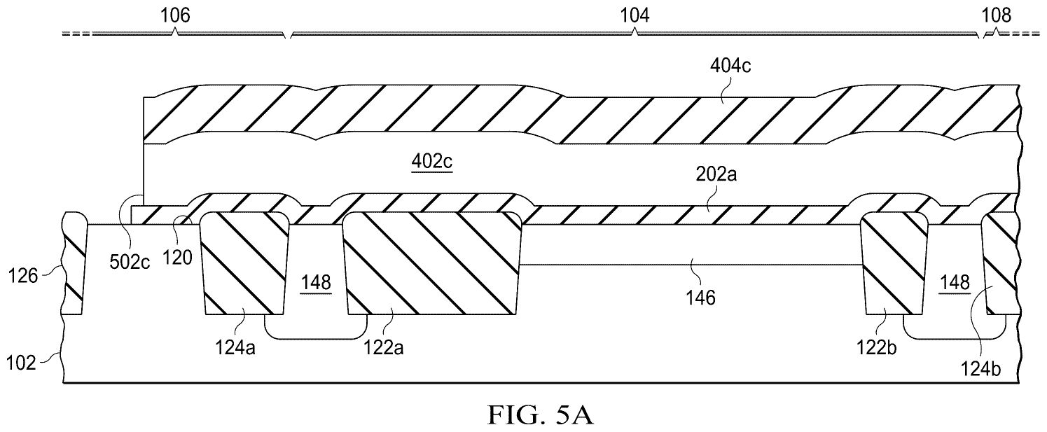

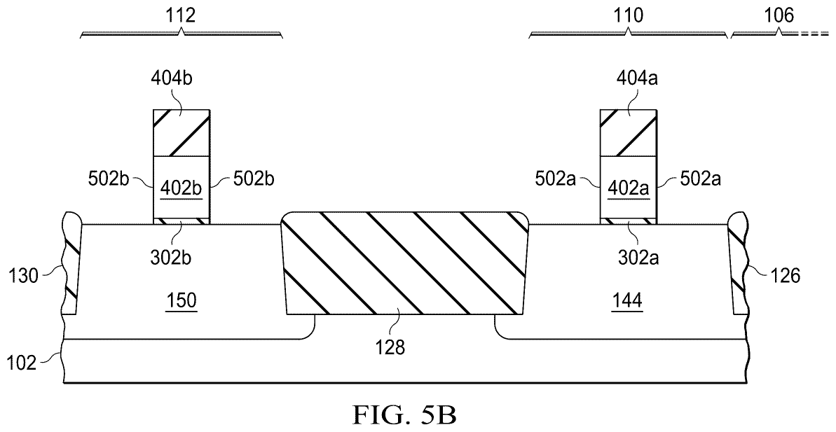

Referring to FIGS. 5A and 5B, the gate layer 402 is patterned into gate electrodes 402a, 402b and residual gate layer 402c, and the gate dielectric layers 302 are patterned into gate dielectric layers 302a, 302b. The hardmask layer 404 is patterned to hardmask layers 404a, 404b, 404c. The hardmask layer 404a is in the pFET region 110, and the hardmask layer 404b is in the nFET region 112. The hardmask layers 404a, 404b are patterned corresponding to the pattern of the gate electrodes 402a, 402b in the pFET region 110 and nFET region 112, respectively. The residual hardmask layer 404c is in the BJT region 104 and extends into the transition regions 106, 108. In the illustrated example, the hardmask layer 404 is patterned using appropriate photolithography and etch (e.g., RIE) processes. Using the patterned hardmask layers 404a, 404b, 404c as a mask, the gate layer 402 and the gate dielectric layers 302 are patterned. The gate layer 402 and the gate dielectric layers 302 are patterned using an appropriate etch process (e.g., RIE).

The gate electrode 402a is over (e.g., on) the gate dielectric layer 302a in the pFET region 110, and the gate electrode 402b is over (e.g., on) the gate dielectric layer 302b in the nFET region 112. The hardmask layers 404a, 404b remain over (e.g., on) the gate electrodes 402a, 402b, respectively. The gate electrode 402a has opposing sidewalls 502a, and the gate dielectric layer 302a and hardmask layer 404a have respective sidewalls that align with the opposing sidewalls 502a. The gate electrode 402b has opposing sidewalls 502b, and the gate dielectric layer 302b and hardmask layer 404b have respective sidewalls that align with the opposing sidewalls 502b.

The residual gate layer 402c is over the pedestal dielectric layer 202a in the BJT region 104 and extends into the transition regions 106, 108. The residual hardmask layer 404c remains over (e.g., on) the residual gate layer 402c. As illustrated, the residual gate layer 402c has a sidewall 502c in the first transition region 106. The sidewall 502c is over the pedestal dielectric layer 202a, and in other examples, the sidewall 502c may be disposed some distance away from the pedestal dielectric layer 202a. An alignment of a lithography mask in the photolithography process for patterning the gate layer 402 (e.g., for patterning the hardmask layer 404) may cause the alignment of the sidewall 502c relative to the pedestal dielectric layer 202a in the first transition region 106 to differ. The residual hardmask layer 404c has a sidewall that aligns with the sidewall 502c. Any of the gate dielectric layer 302 in the first transition region 106 that becomes exposed as a result of patterning the gate layer 402 may be removed, such as illustrated. Depending on alignment of the sidewall 502c, in some examples, a portion of the gate dielectric layer 302 may remain in the first transition region 106 under the residual gate layer 402c.

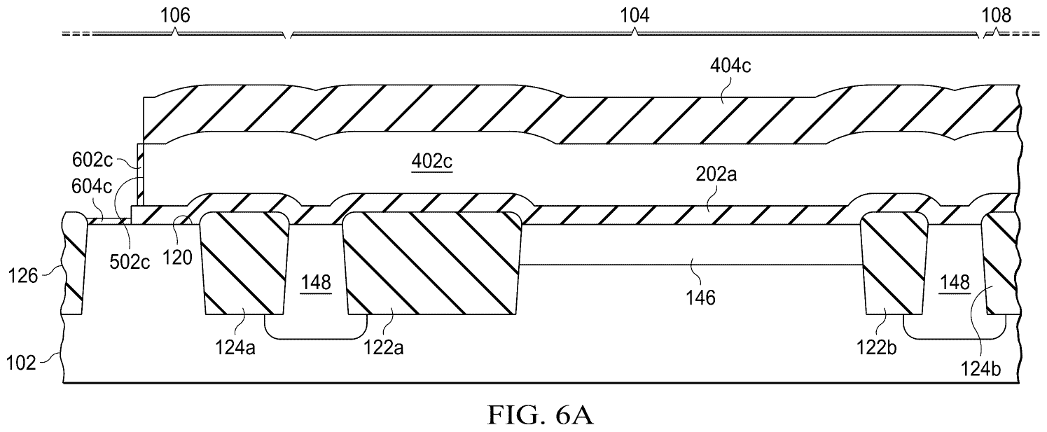

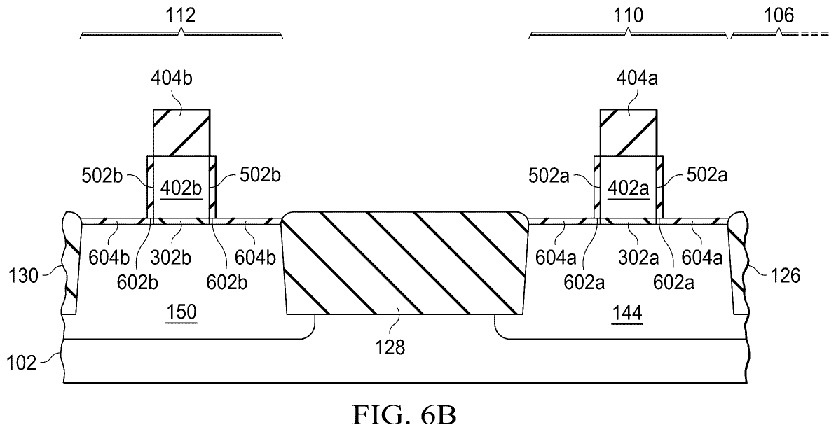

Referring to FIGS. 6A and 6B, reoxidation layers 602a, 602b are formed along the sidewalls 502a, 502b of the gate electrodes 402a, 402b. The reoxidation layers 602a, 602b may be formed by oxidizing the sidewalls 502a, 502b of the gate electrodes 402a, 402b, such as by ISSG oxidation. In some examples, the oxidation process may be performed at 750° C. or more for 45 seconds or more. The formation of the reoxidation layers 602a, 602b may remove damage on the sidewalls 502a, 502b of the gate electrodes 402a, 402b formed by the etch process that patterns the gate electrodes 402a, 402b, which damage may be plasma-induced. The formation of the reoxidation layers 602a, 602b may reduce gate-induced drain leakage current in the FETs (that include the gate electrodes 402a, 402b) that are to be formed.

Formation of the reoxidation layers 602a, 602b before formation of layers of the BJT (e.g., the collector layer, the base layer, the emitter layer, and/or, if applicable, a raised base layer) permits a higher thermal budget for forming the reoxidation layers 602a, 602b. Without the layers of the BJT being present, concerns for outdiffusion and/or outgassing of dopants of those layers in high temperature processes is obviated for the formation of the reoxidation layers 602a, 602b. The formation of the reoxidation layers 602a, 602b may further form a reoxidation layer 602c, e.g., on the sidewall 502c of the residual gate layer 402c. Additionally, the formation of the reoxidation layers 602a, 602b may further form reoxidation layers 604a, 604b, 604c on exposed portions of the upper surface 120 of the semiconductor substrate 102.

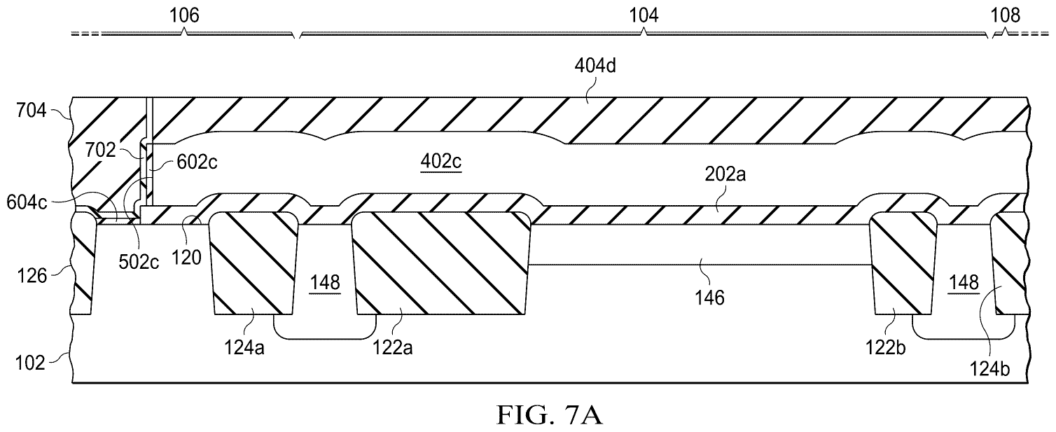

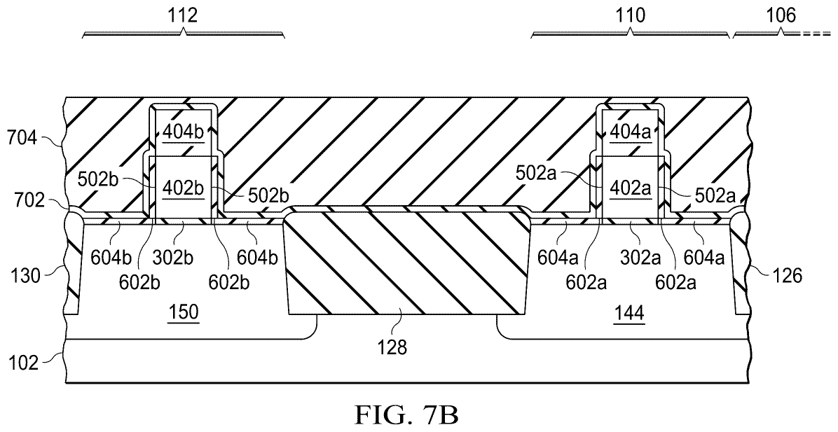

Referring to FIGS. 7A and 7B, an etch stop layer 702 is formed conformally over the semiconductor substrate 102, and a fill material 704 is formed over the etch stop layer 702. The etch stop layer 702 is formed, in the pFET region 110, conformally over the reoxidation layers 604a, along the reoxidation layers 602a, and over the hardmask layer 404a and, in the nFET region 112, conformally over the reoxidation layers 604b, along the reoxidation layers 602b, and over the hardmask layer 404b. In the first transition region 106, the etch stop layer 702 is formed conformally over the isolation structure 126, the reoxidation layer 604c, along a sidewall and over an upper surface of the pedestal dielectric layer 202a, along the reoxidation layer 602c, and along a sidewall of the residual hardmask layer 404c. The etch stop layer 702 may be formed using a deposition process, such as CVD, atomic layer deposition (ALD), or the like. When deposited, the etch stop layer 702 may further be deposited over an upper surface of the residual hardmask layer 404c in the transition regions 106, 108 and the BJT region 104. The etch stop layer 702 may be or include silicon nitride or another material that permits etch selectivity.

After depositing the etch stop layer 702, the fill material 704 is deposited over the etch stop layer 702. The fill material 704 may be or include a dielectric material or any other material that is suitable for filling the pFET region 110 and nFET region 112 during subsequent processing. In some examples, the fill material 704 may be or include a silicon oxide (e.g., a TEOS oxide). The fill material 704 may be deposited by CVD. Other materials (which are different from a material of the etch stop layer 702 to permit etch selectivity) and/or other deposition processes may be used in other examples.

After depositing the fill material 704, a planarization process is performed. In some examples, the planarization process is a CMP. Any fill material 704 and etch stop layer 702 over the residual hardmask layer 404c (e.g., in the BJT region 104 and in the transition regions 106, 108) is removed by the planarization process. The planarization process further planarizes and removes a portion of the residual hardmask layer 404c resulting in the residual hardmask layer 404d. The planarization process causes the top surfaces of the residual hardmask layer 404d, the fill material 704, and the etch stop layer 702 to be co-planar. The fill material 704 may remain over the hardmask layers 404a, 404b in the pFET region 110 and nFET region 112 after the planarization process. In some examples, the planarization process may reach the hardmask layers 404a, 404b—e.g., exposing the hardmask layers 404a, 404b.

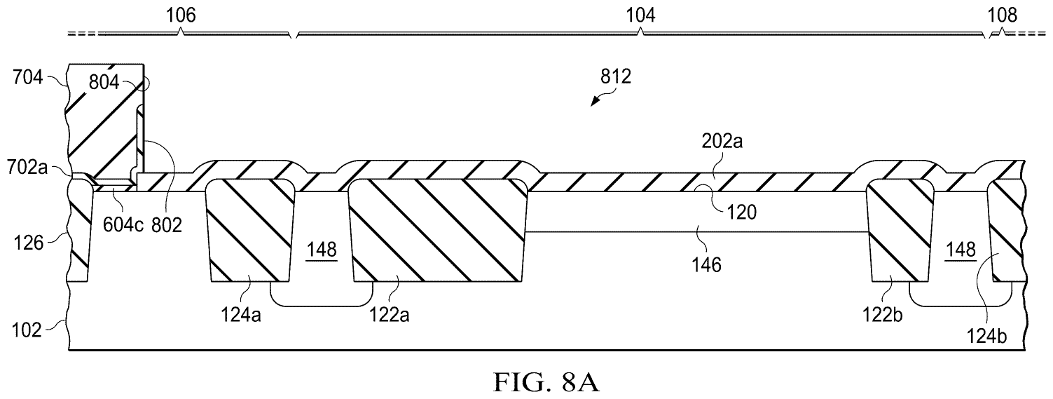

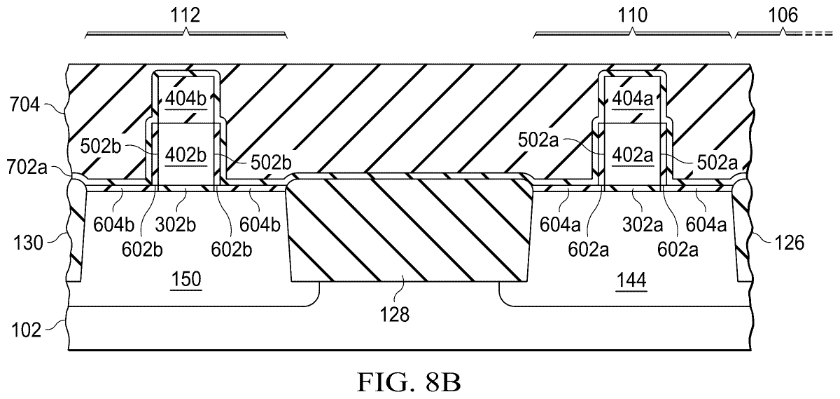

Referring to FIGS. 8A and 8B, the residual hardmask layer 404d and residual gate layer 402c are removed from the BJT region 104 and the transition regions 106, 108. Removing the residual hardmask layer 404d and the residual gate layer 402c exposes the pedestal dielectric layer 202a in the BJT region 104 and the transition regions 106, 108. The residual hardmask layer 404d may be removed using an etch process selective to the material of the residual hardmask layer 404d, which may be a wet or dry process and may be an isotropic etch process. Etching the residual hardmask layer 404d with, e.g., a wet, isotropic etch process may etch the etch stop layer 702 (e.g., when the residual hardmask layer 404d and etch stop layer 702 are both silicon nitride) that becomes exposed during etching the residual hardmask layer 404d, which results in etch stop layer 702a. The residual gate layer 402c may be removed using an etch process selective to the material of the residual gate layer 402c, which may be a wet or dry process and may be an isotropic etch process. The etch process to remove the residual gate layer 402c may further remove the reoxidation layer 602c. In some examples, the CFET region may be masked, such as by a hardmask layer (of a material different from the materials of the hardmask layer 404 and gate layer 402) and/or photoresist, during the etching of the residual hardmask layer 404d and the residual gate layer 402c.

After removing the residual hardmask layer 404d and residual gate layer 402c, the etch stop layer 702a has a sidewall 802 in the first transition region 106 where the etch stop layer 702 interfaced with the reoxidation layer 602c and/or residual gate layer 402c prior to removal of the reoxidation layer 602c and/or residual gate layer 402c. Further, the fill material 704 has a sidewall 804 where the etch stop layer 702 was etched back by the etch to remove the residual hardmask layer 404d. In some examples, the etch stop layer 702a and fill material 704 may laterally encircle or encompass the BJT region 104 (and further, portions of the transition regions 106, 108). The sidewalls 802, 804 may, in such circumstances, define an opening 812 at least in the BJT region 104 through which the BJT is to be formed.

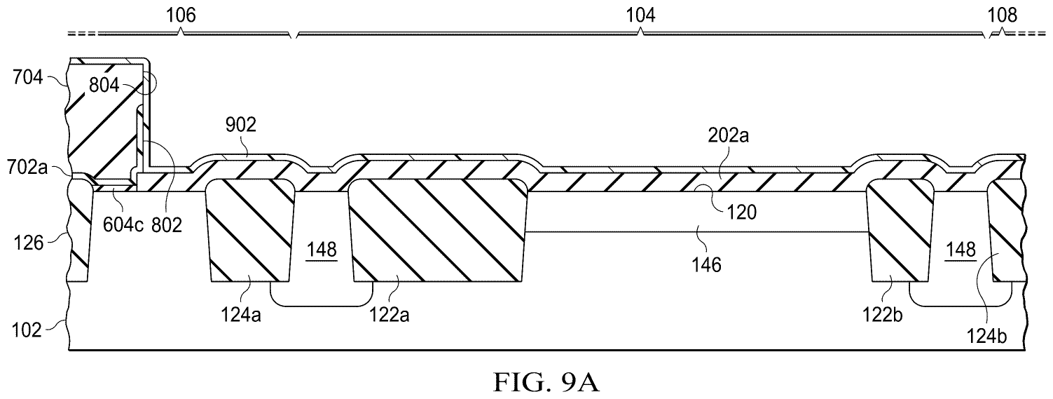

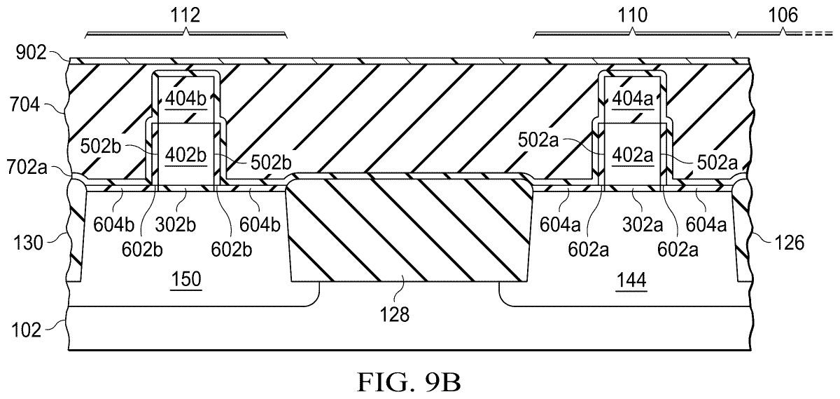

Referring to FIGS. 9A and 9B, a hardmask layer 902 is formed conformally over the semiconductor substrate 102. The hardmask layer 902 is conformally over the pedestal dielectric layer 202a exposed in the BJT region 104 and transition regions 106, 108, over the fill material in the pFET region 110, nFET region 112, and first transition region 106, and along the sidewalls 802, 804 of the etch stop layer 702a and fill material 704 in the first transition region 106. In some examples, the hardmask layer 902 is or includes silicon nitride deposited by CVD, although other hardmask (e.g., dielectric) materials and/or other deposition processes may be used in other examples.

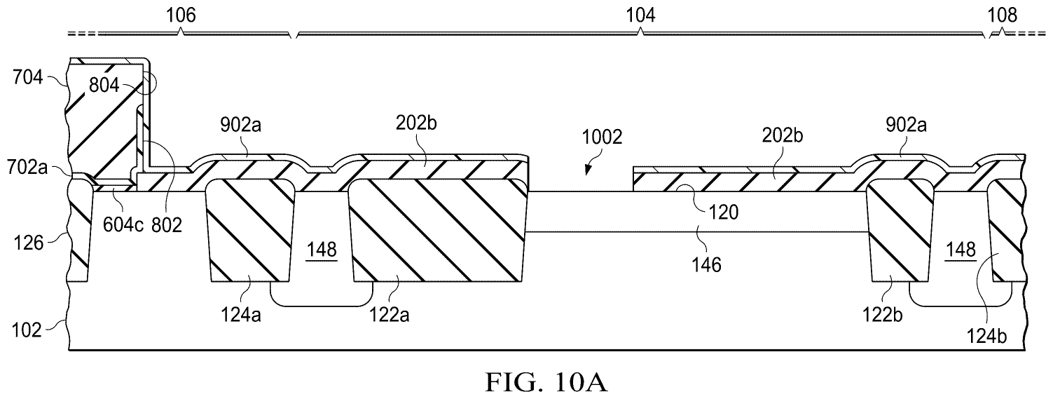

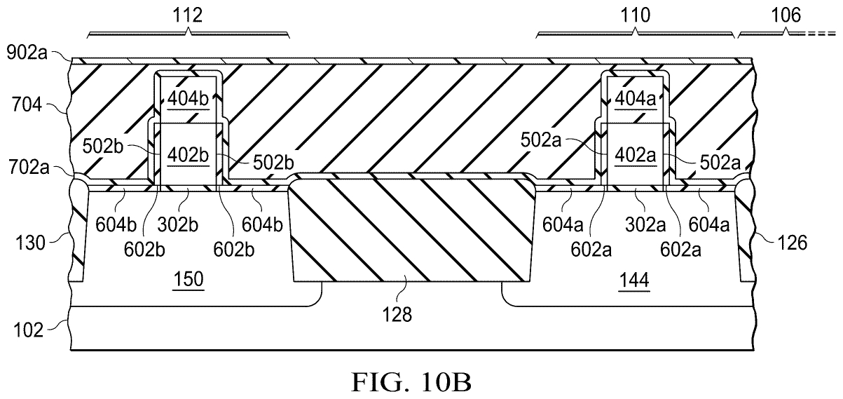

Referring to FIGS. 10A and 10B, the hardmask layer 902 and the pedestal dielectric layer 202a are etched to form a collector opening 1002 through the hardmask layer 902a and the pedestal dielectric layer 202b. The upper surface 120 of the semiconductor substrate 102 is exposed through the collector opening 1002. The collector opening 1002 generally extends from proximate to (or some lateral distance from) the first portion 122a of the isolation structure 122 laterally away from the first portion 122a of the isolation structure 122 in the BJT region 104. The collector opening 1002 may be formed through the hardmask layer 902a and pedestal dielectric layer 202a using appropriate photolithography and etch (e.g., RIE) processes.

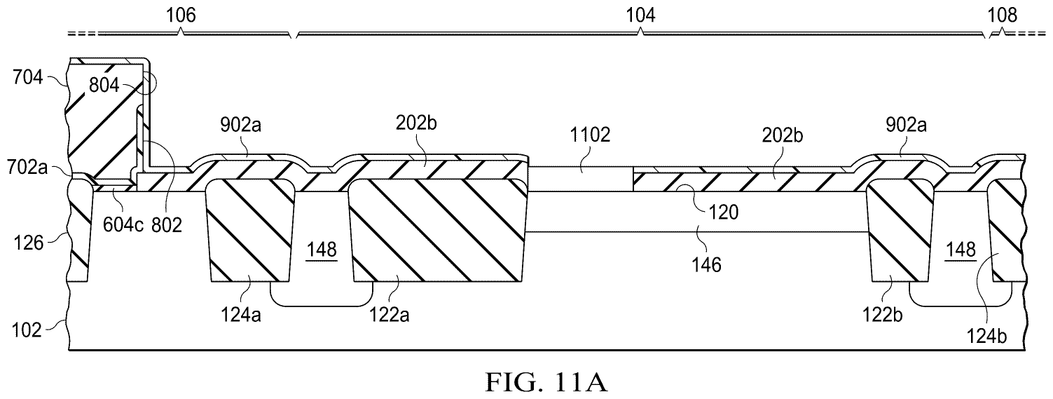

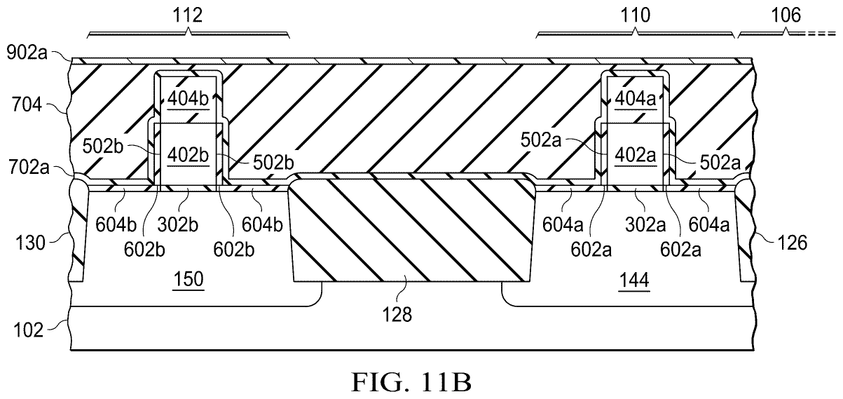

Referring to FIGS. 11A and 11B, a collector layer 1102 is formed over (e.g., on) the upper surface 120 of the semiconductor substrate 102 and in the collector opening 1002. In some examples, the collector layer 1102 is or includes a semiconductor layer doped with an n-type dopant (e.g., a same dopant type as the n-type doped sub-collector diffusion region 146). In some examples, the collector layer 1102 is or includes silicon. In some examples, the collector layer 1102 is doped with an n-type dopant with a concentration in a range from 1×10¹⁹ cm⁻³ to 1×10²¹ cm⁻³. The collector layer 1102 may be epitaxially grown on the upper surface 120 of the semiconductor substrate 102. The collector layer 1102 may be epitaxially grown by a selective epitaxial growth process in some examples. The epitaxial growth of the collector layer 1102 on the upper surface 120 of the semiconductor substrate 102 may result in the collector layer 1102 being monocrystalline. Further, the collector layer 1102 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

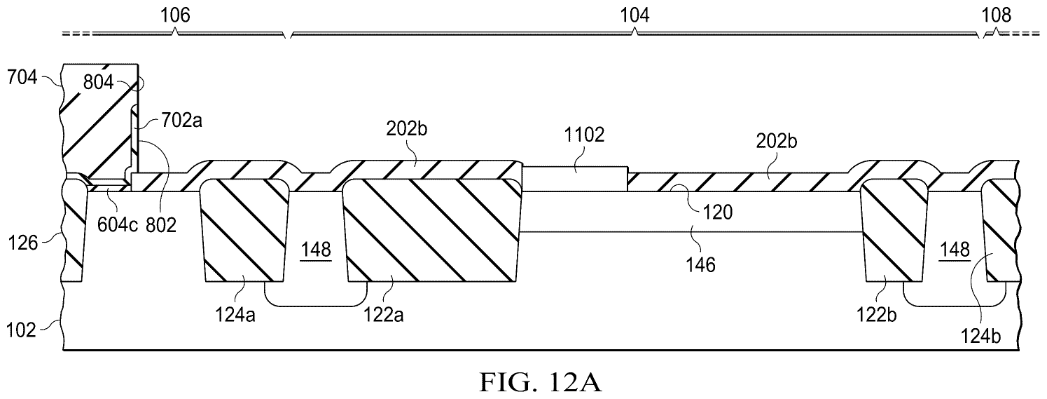

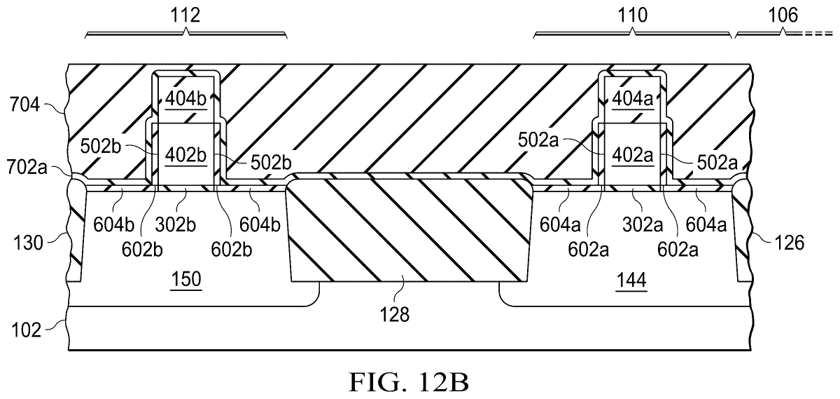

Referring to FIGS. 12A and 12B, the hardmask layer 902a is removed. The hardmask layer 902a may be removed using an etch selective to the material of the hardmask layer 902a. The etch process may be a wet or dry etch process and may be isotropic. For example, when the hardmask layer 902a is silicon nitride, the etch process may be or include using phosphoric acid, which may also reduce the etch stop layer 702a (not illustrated).

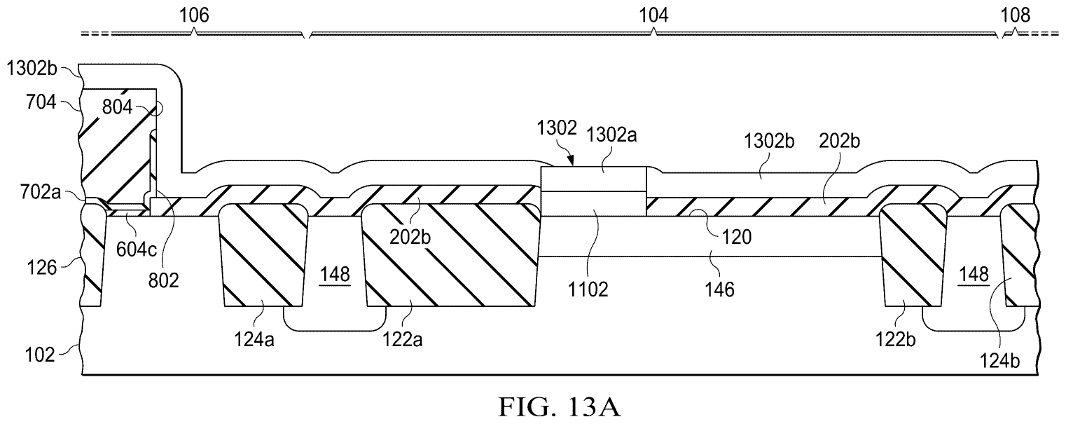

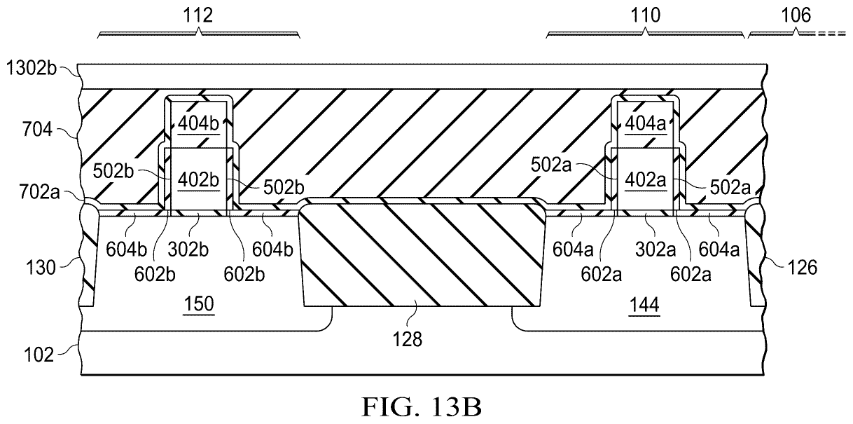

Referring to FIGS. 13A and 13B, a base layer 1302 is formed over the collector layer 1102. The base layer 1302 includes a monocrystalline base layer 1302a and a polycrystalline base layer 1302b. The monocrystalline base layer 1302a and polycrystalline base layer 1302b together form the base layer 1302. In some examples, the base layer 1302 is or includes a semiconductor layer doped with a p-type dopant (e.g., an opposite dopant type as the collector layer 1102). In some examples, the base layer 1302 is or includes silicon germanium. In some examples, the base layer 1302 is doped with a p-type dopant with a concentration in a range from 1×10¹⁷ cm⁻³ to 1×10²¹ cm⁻³. The base layer 1302 may also be doped with carbon (C) to prevent or reduce diffusion of the p-type dopant. The base layer 1302 may be epitaxially grown on the collector layer 1102, the pedestal dielectric layer 202b, the etch stop layer 702a, and the fill material 704. The base layer 1302 may be epitaxially grown by a non-selective epitaxial growth process in some examples. The non-selective epitaxial growth process grows the monocrystalline base layer 1302a from the collector layer 1102 and grows the polycrystalline base layer 1302b on other amorphous or polycrystalline surfaces, such as the pedestal dielectric layer 202b, the etch stop layer 702a, and the fill material 704. Further, the polycrystalline base layer 1302b is grown on the sidewall 802 of the etch stop layer 702a and the sidewall 804 of the fill material 704. The monocrystalline base layer 1302a may meet the polycrystalline base layer 1302b at a facet that is not specifically illustrated. The non-selective deposition of the base layer 1302 forms the base layer 1302 conformally. The base layer 1302 may be in situ doped during the epitaxial growth process. The base layer 1302 (e.g., the monocrystalline base layer 1302a and polycrystalline base layer 1302b each) may further include multiple sub-layers, such as a nucleation sub-layer of the same material as the collector layer 1102, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

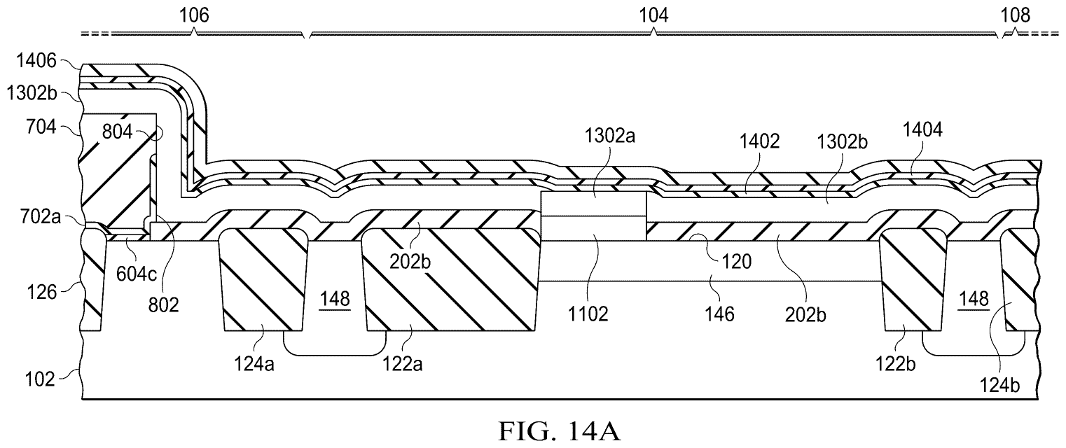

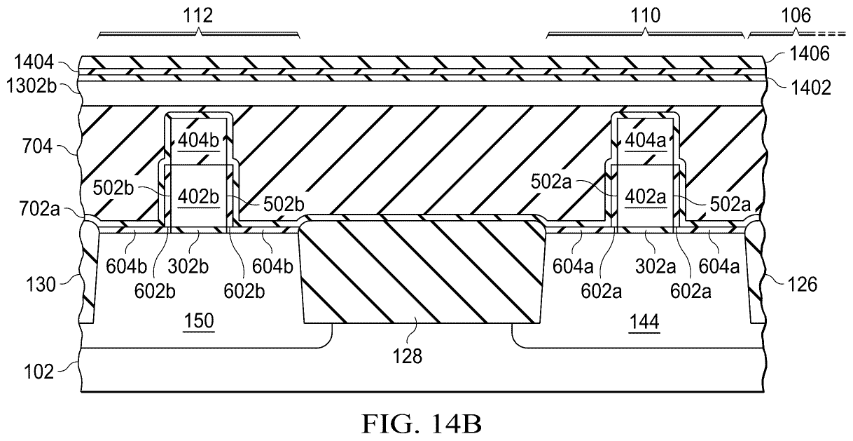

Referring to FIGS. 14A and 14B, a first dielectric spacer layer 1402 is formed conformally over the base layer 1302. A second dielectric spacer layer 1404 is formed conformally over the first dielectric spacer layer 1402, and a third dielectric spacer layer 1406 is formed conformally over the second dielectric spacer layer 1404. In some examples, the first dielectric spacer layer 1402 and third dielectric spacer layer 1406 are a same dielectric material, and the second dielectric spacer layer 1404 is a dielectric material different from the dielectric material of the first dielectric spacer layer 1402 and third dielectric spacer layer 1406. In some examples, the first dielectric spacer layer 1402 and third dielectric spacer layer 1406 are silicon oxide (e.g., a TEOS oxide), and the second dielectric spacer layer 1404 is silicon nitride. The dielectric spacer layers 1402-1406 may be deposited by CVD. Other dielectric materials and/or other deposition processes may be used in other examples.

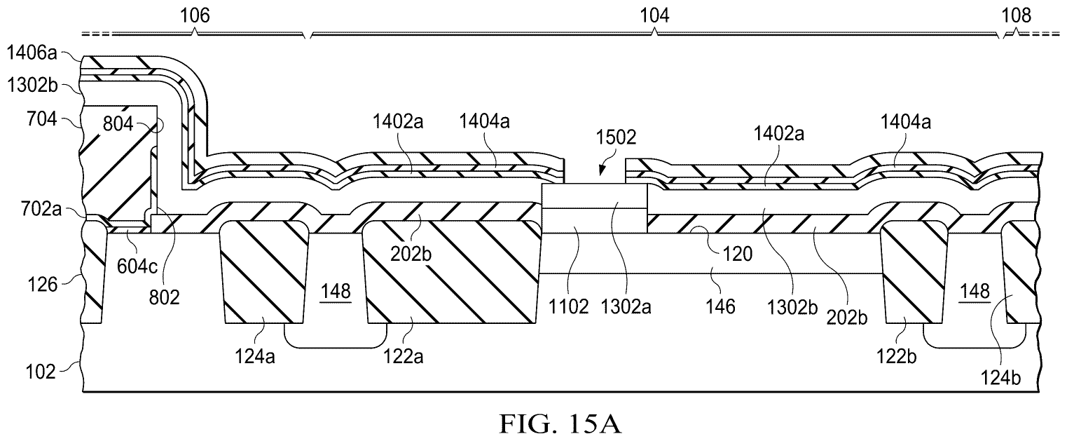

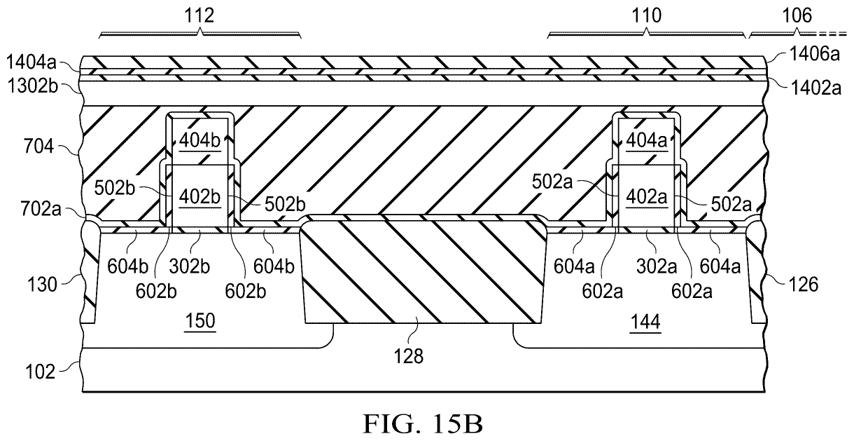

Referring to FIGS. 15A and 15B, the dielectric spacer layers 1402-1406 are etched to form a first emitter opening 1502 through the first dielectric spacer layer 1402a, second dielectric spacer layer 1404a, and third dielectric spacer layer 1406a. The monocrystalline base layer 1302a (of the base layer 1302) is exposed through the first emitter opening 1502. The first emitter opening 1502 is in the BJT region 104. The dielectric spacer layers 1402a, 1404a, 1406a may be patterned using appropriate photolithography and etch (e.g., RIE) processes.

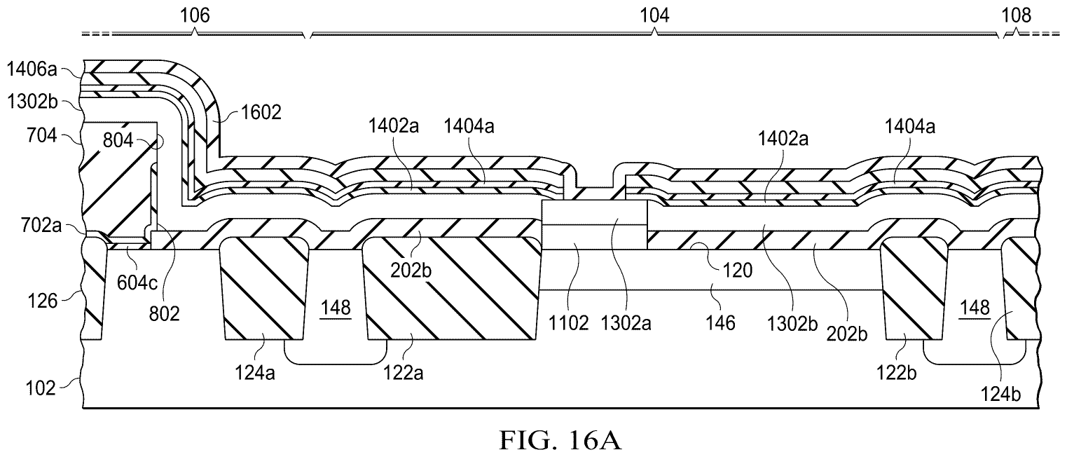

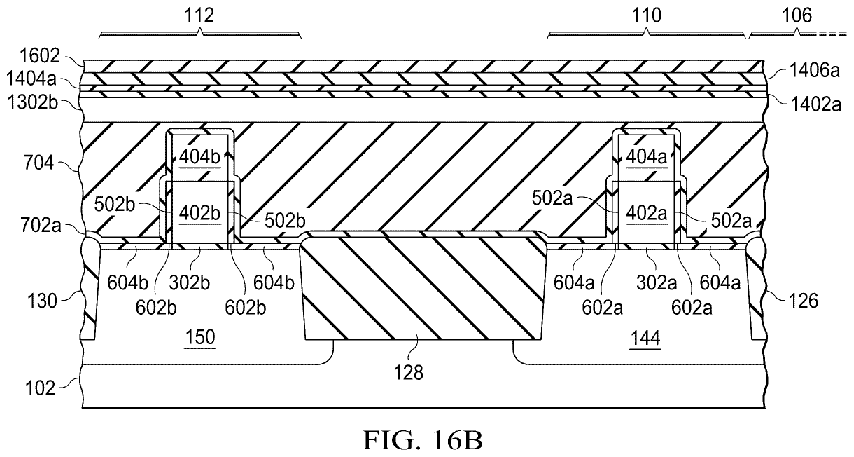

Referring to FIGS. 16A and 16B, an emitter dielectric spacer layer 1602 is conformally formed over the third dielectric spacer layer 1406a and in the first emitter opening 1502. The emitter dielectric spacer layer 1602 is formed on sidewalls of the dielectric spacer layers 1402-1406 and the upper surface of the monocrystalline base layer 1302a that define the first emitter opening 1502. In some examples, the emitter dielectric spacer layer 1602 is silicon oxide (e.g., a TEOS oxide) deposited by CVD, although other dielectric materials and/or other deposition processes may be used in other examples.

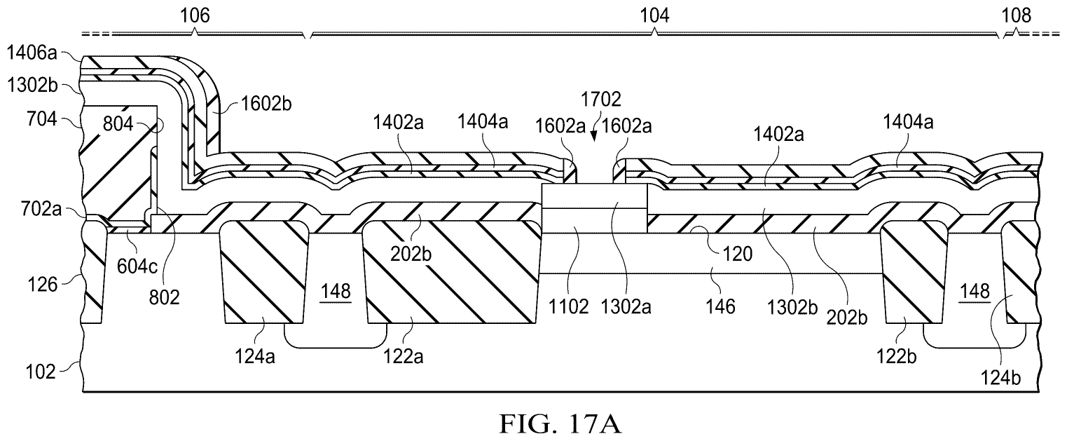

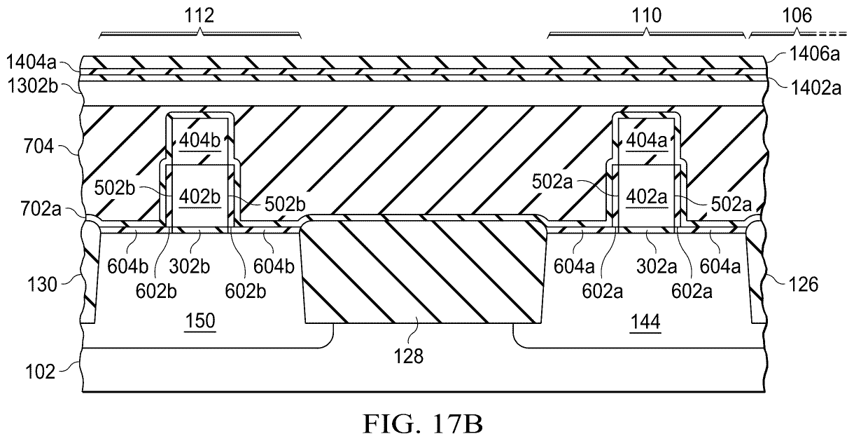

Referring to FIGS. 17A and 17B, the emitter dielectric spacer layer 1602 is anisotropically etched to form emitter dielectric spacers 1602a along sidewalls of the dielectric spacer layers 1402a, 1404a, 1406a that define the first emitter opening 1502. The emitter dielectric spacers 1602a constrict the first emitter opening 1502 to form a second emitter opening 1702. Additionally, a residual dielectric spacer 1602b may remain on a vertical surface, such as a vertical surface of the third dielectric spacer layer 1406a—e.g., as shown in the first transition region 106. The anisotropic etch may be an RIE, for example.

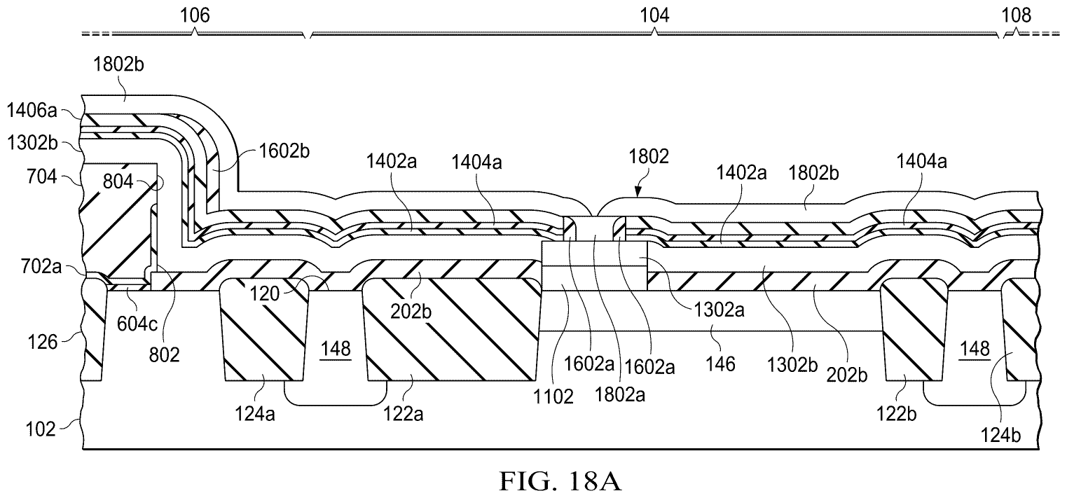

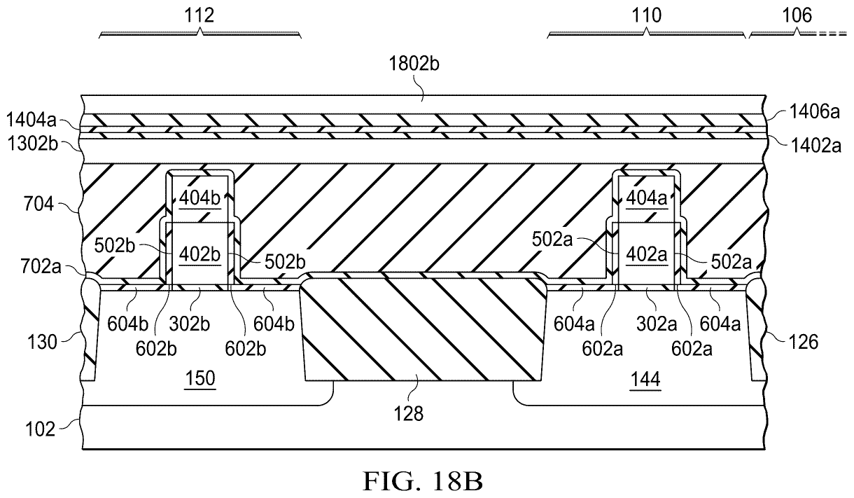

Referring to FIGS. 18A and 18B, an emitter layer 1802 is formed over the base layer 1302 (e.g., on the monocrystalline base layer 1302a). The emitter layer 1802 includes a monocrystalline emitter layer 1802a and a polycrystalline emitter layer 1802b. The monocrystalline emitter layer 1802a and polycrystalline emitter layer 1802b together form the emitter layer 1802. In some examples, the emitter layer 1802 is or includes a semiconductor layer doped with an n-type dopant (e.g., an opposite dopant type from the base layer 1302). In some examples, the emitter layer 1802 is or includes silicon. In some examples, the emitter layer 1802 is doped with an n-type dopant with a concentration in a range from 1×10¹⁹ cm⁻³ to 1×10²¹ cm⁻³. The emitter layer 1802 may be epitaxially grown on the base layer 1302 (e.g., the monocrystalline base layer 1302a) exposed through the second emitter opening 1702, the emitter dielectric spacers 1602a, the third dielectric spacer layer 1406a, and the residual dielectric spacer 1602b. The emitter layer 1802 may be epitaxially grown by a non-selective epitaxial growth process in some examples. The non-selective epitaxial growth process grows the monocrystalline emitter layer 1802a from the monocrystalline base layer 1302a and grows the polycrystalline emitter layer 1802b on other amorphous or polycrystalline surfaces, such as the emitter dielectric spacers 1602a, the third dielectric spacer layer 1406a, and the residual dielectric spacer 1602b. The monocrystalline emitter layer 1802a may meet the polycrystalline emitter layer 1802b at a facet that is not specifically illustrated. The non-selective deposition of the emitter layer 1802 forms the emitter layer 1802 conformally. The emitter layer 1802 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

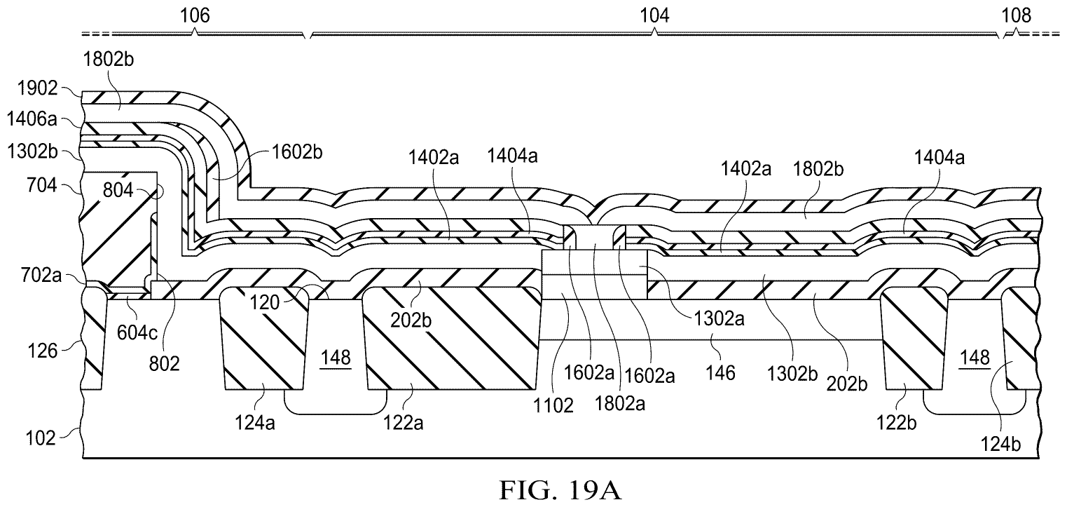

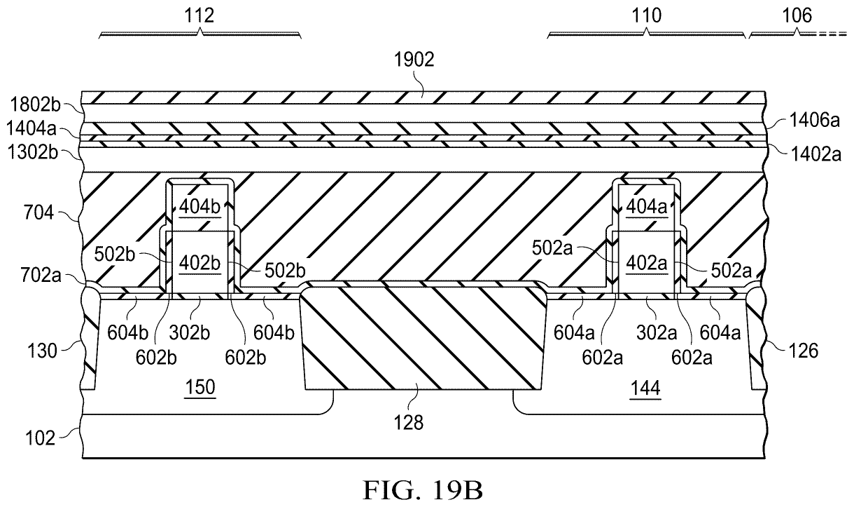

Referring to FIGS. 19A and 19B, an emitter dielectric cap layer 1902 is conformally formed over the emitter layer 1802. In some examples, the emitter dielectric cap layer 1902 is silicon oxide (e.g., a TEOS oxide) deposited by CVD, although other dielectric materials and/or other deposition processes may be used in other examples.

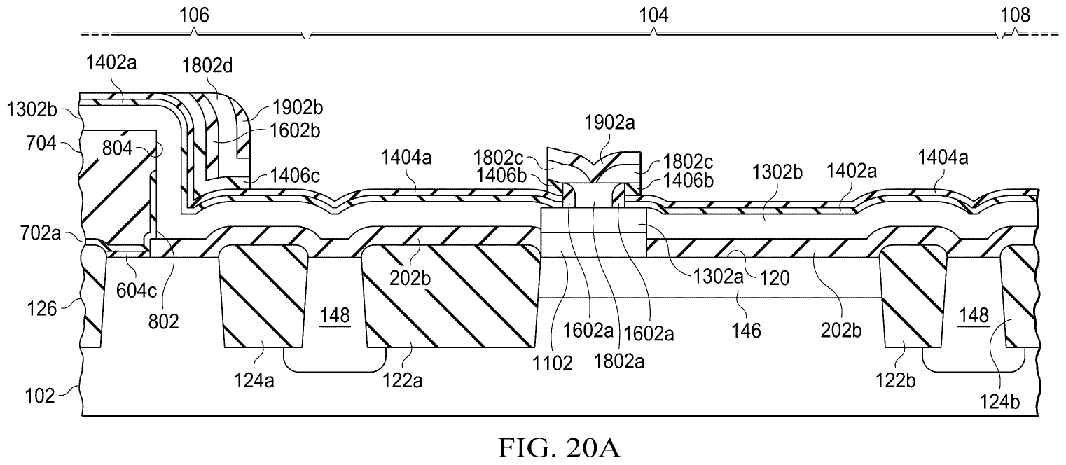

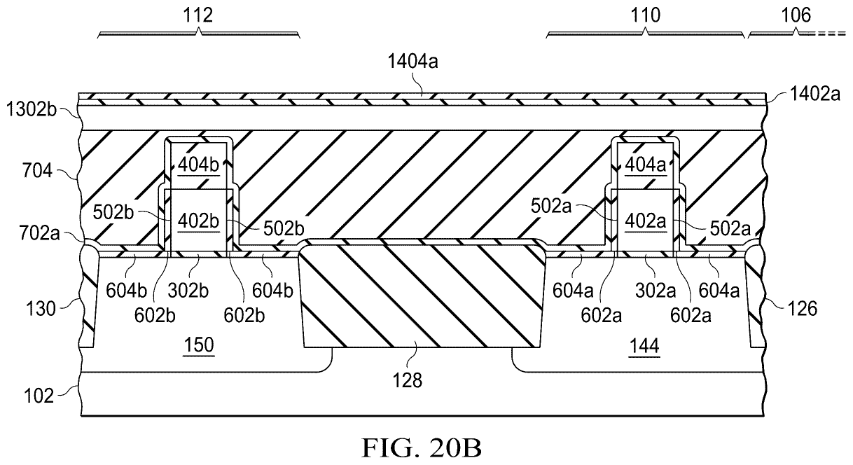

Referring to FIGS. 20A and 20B, the emitter dielectric cap layer 1902, polycrystalline emitter layer 1802b, and third dielectric spacer layer 1406a are etched to form the emitter dielectric cap layer 1902a, polycrystalline emitter layer 1802c, and third dielectric spacer 1406b in the BJT region 104. In the illustrated example, the layers 1902, 1802b, 1406a are patterned using appropriate photolithography and etch (e.g., anisotropic etch, such as RIE) processes. Anisotropically etching the emitter dielectric cap layer 1902, polycrystalline emitter layer 1802b, and third dielectric spacer layer 1406a may result in residual portions of those layers, e.g., at or near sidewalls 802, 804 in the first transition region 106. As illustrated, a residual emitter dielectric cap spacer 1902b, a residual polycrystalline emitter spacer 1802d, and a residual third dielectric spacer 1406c, along with the residual dielectric spacer 1602b, remain in the first transition region 106 at or near the sidewalls 802, 804.

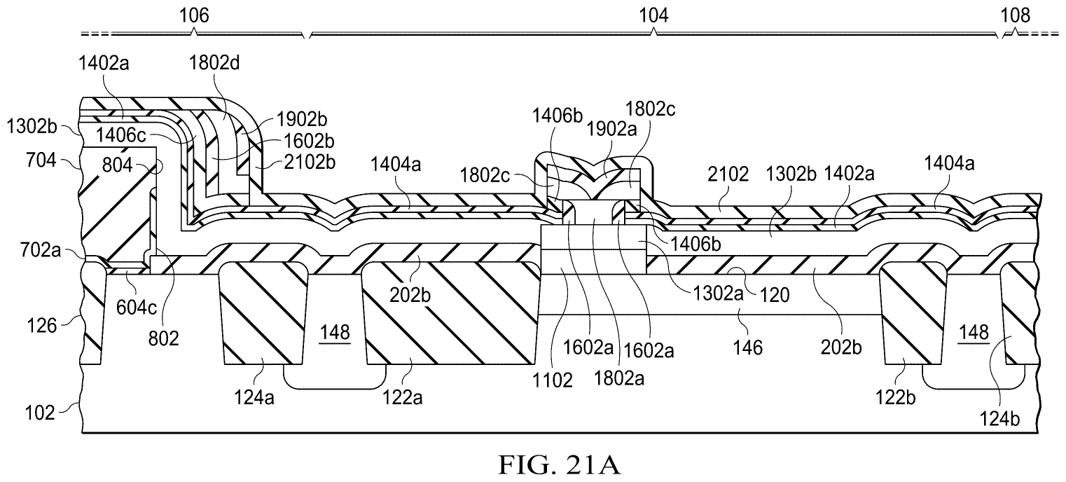

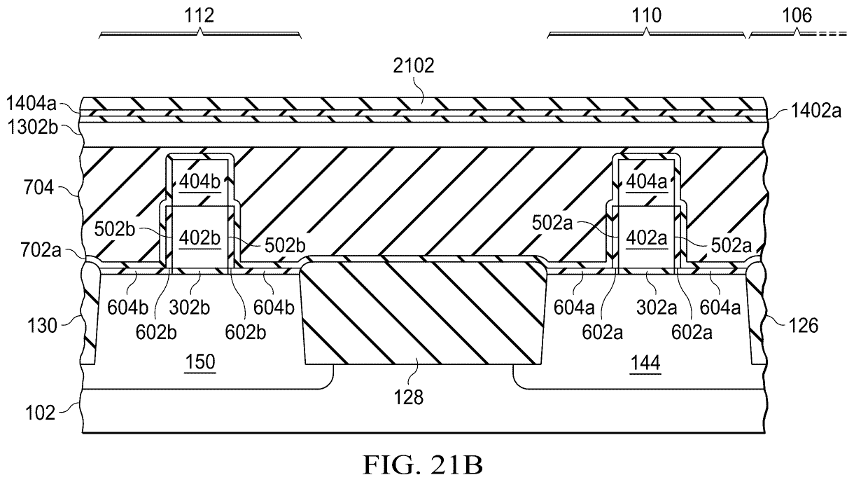

Referring to FIGS. 21A and 21B, an emitter dielectric protective spacer layer 2102 is conformally formed over the emitter dielectric cap layer 1902a and the second dielectric spacer layer 1404a and along sidewalls of the emitter dielectric cap layer 1902a, polycrystalline emitter layer 1802c, and third dielectric spacer 1406b. Additionally, the emitter dielectric protective spacer layer 2102 is conformally formed over the residual spacers 1406c, 1602b, 1802d, 1902b. In some examples, the emitter dielectric protective spacer layer 2102 is silicon oxide (e.g., a TEOS oxide) deposited by CVD, although other dielectric materials and/or other deposition processes may be used in other examples.

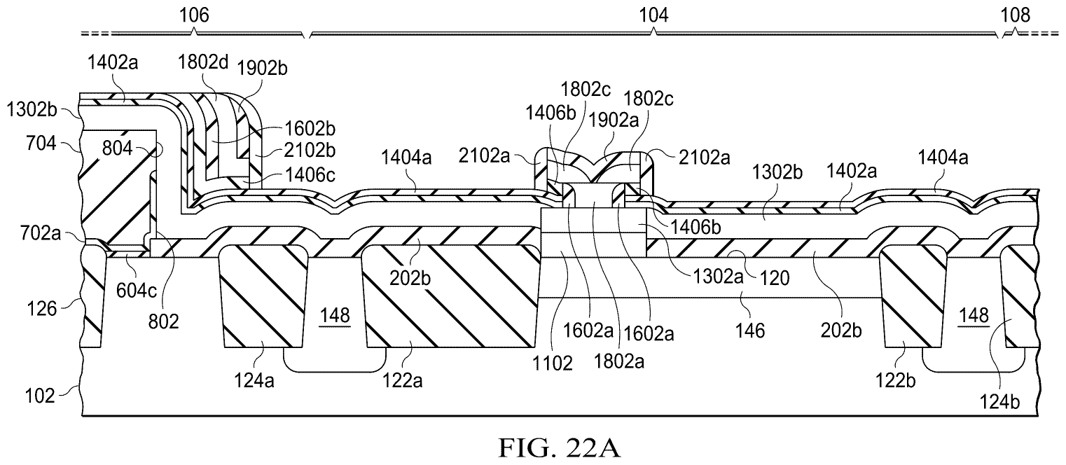

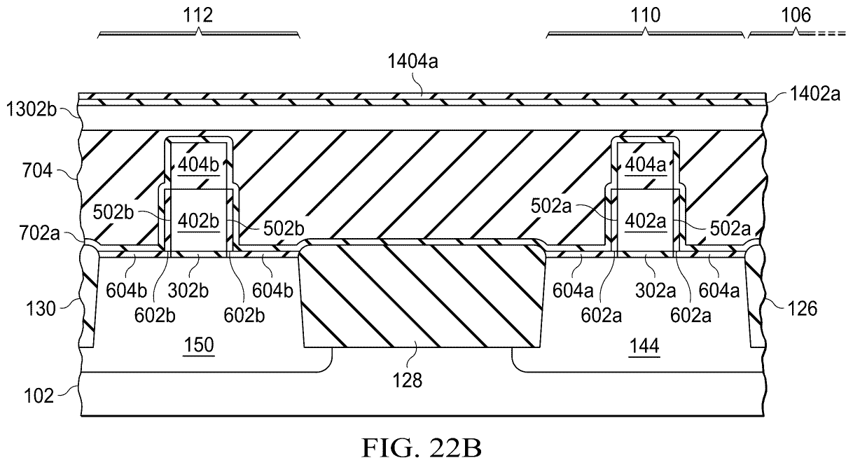

Referring to FIGS. 22A and 22B, the emitter dielectric protective spacer layer 2102 is anisotropically etched to form emitter dielectric protective spacers 2102a along sidewalls of the emitter dielectric cap layer 1902a, polycrystalline emitter layer 1802c, and third dielectric spacer 1406b. The emitter dielectric protective spacers 2102a protect sidewalls of the polycrystalline emitter layer 1802c, e.g., during a subsequent epitaxial growth process. Additionally, a residual dielectric spacer 2102b may remain on a vertical surface, such as a vertical surface of the residual spacers 1902b, 1802d, 1406c. The anisotropic etch may be an RIE, for example.

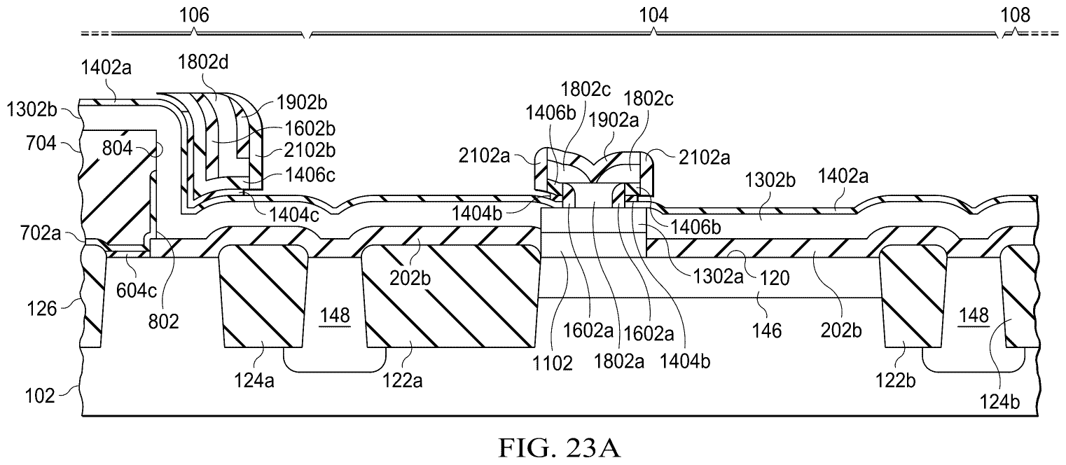

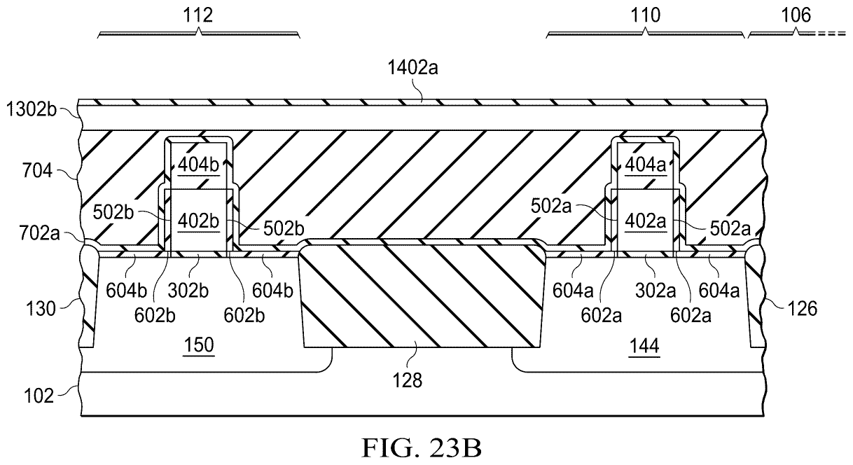

Referring to FIGS. 23A and 23B, the second dielectric spacer layer 1404a is etched. The etch removes exposed portions of the second dielectric spacer layer 1404a and undercuts the emitter dielectric protective spacers 2102a and third dielectric spacers 1406b laterally distal from the monocrystalline emitter layer 1802a, which results in second dielectric spacers 1404b under the third dielectric spacers 1406b. The etch may also undercut any of the residual spacers 2102b, 1902b, 1802d, 1406c, which further forms residual second dielectric spacers 1404c—e.g., as shown in the first transition region 106. The etch may be a wet or dry etch selective to the material of the second dielectric spacer layer 1404a, which etch is also isotropic. For example, when the second dielectric spacer layer 1404a is silicon nitride, the etch process may be or include using phosphoric acid.

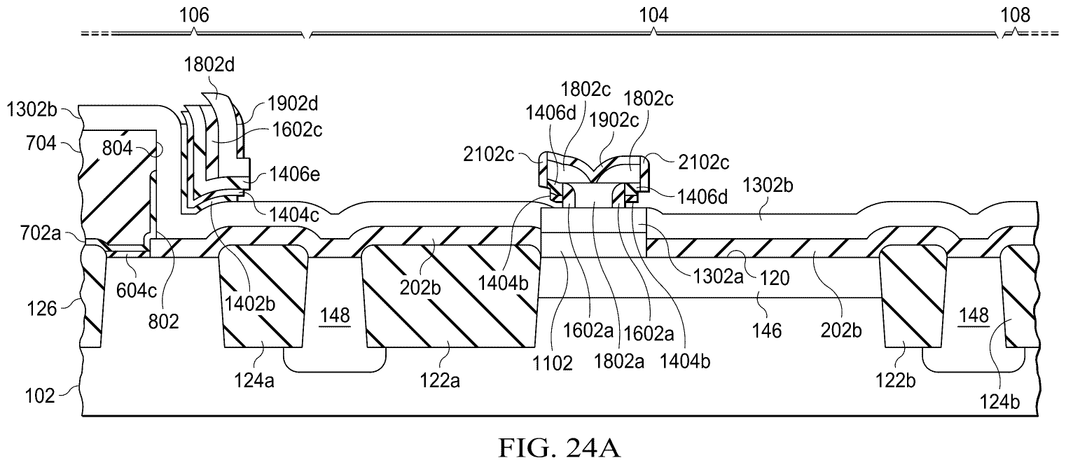

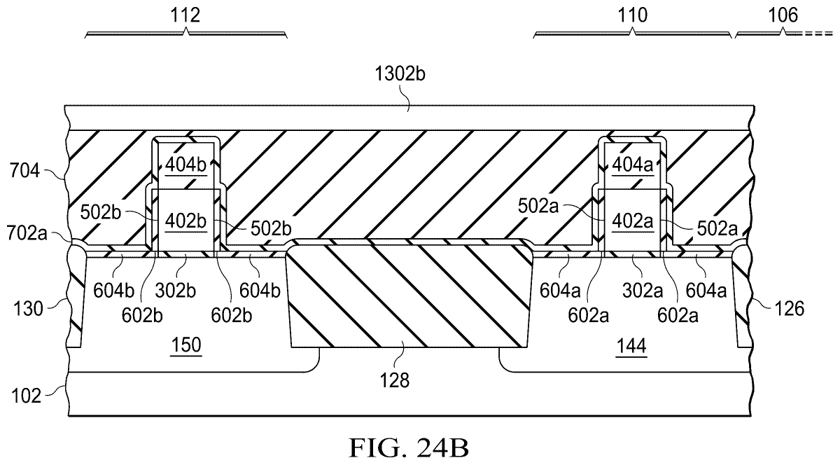

Referring to FIGS. 24A and 24B, the first dielectric spacer layer 1402a is etched. Etching the first dielectric spacer layer 1402a removes exposed portions of the first dielectric spacer layer 1402a, such as from the monocrystalline base layer 1302a. A residual first dielectric spacer 1402b, as illustrated in the first transition region 106, remains under the residual second dielectric spacer 1404c. The etch may be a wet etch selective to the first dielectric spacer layer 1402a. For example, when the first dielectric spacer layer 1402a is silicon oxide, the first dielectric spacer layer 1402a may be etched using a dilute hydrochloric acid (dHCl) etch. A wet etch may remove the first dielectric spacer layer 1402a that underlies the emitter dielectric protective spacers 2102a and the second dielectric spacers 1404b. Additionally, the wet etch may further etch the emitter dielectric cap layer 1902a, emitter dielectric protective spacers 2102a, and the third dielectric spacers 1406b, which reduces respective thicknesses of those layers and spacers and results in emitter dielectric cap layer 1902c, emitter dielectric protective spacers 2102c, and third dielectric spacers 1406d when those layers and spacers are a same material as the first dielectric spacer layer 1402a, such as illustrated. Additionally, as illustrated in the first transition region 106, the wet etch may further etch the residual dielectric spacer 2102b, the residual emitter dielectric cap spacer 1902b, the residual dielectric spacer 1602b, and the residual third dielectric spacer 1406c, which reduces spacers resulting in a residual emitter dielectric cap spacer 1902d, a residual dielectric spacer 1602c, and a residual third dielectric spacer 1406e and removes the residual dielectric spacer 2102b, when those spacers are a same material as the first dielectric spacer layer 1402a, such as illustrated. The removal of the first dielectric spacer layer 1402a opens (e.g., exposes) an area on the base layer 1302 near the monocrystalline emitter layer 1802a on which a raised base layer may be formed.

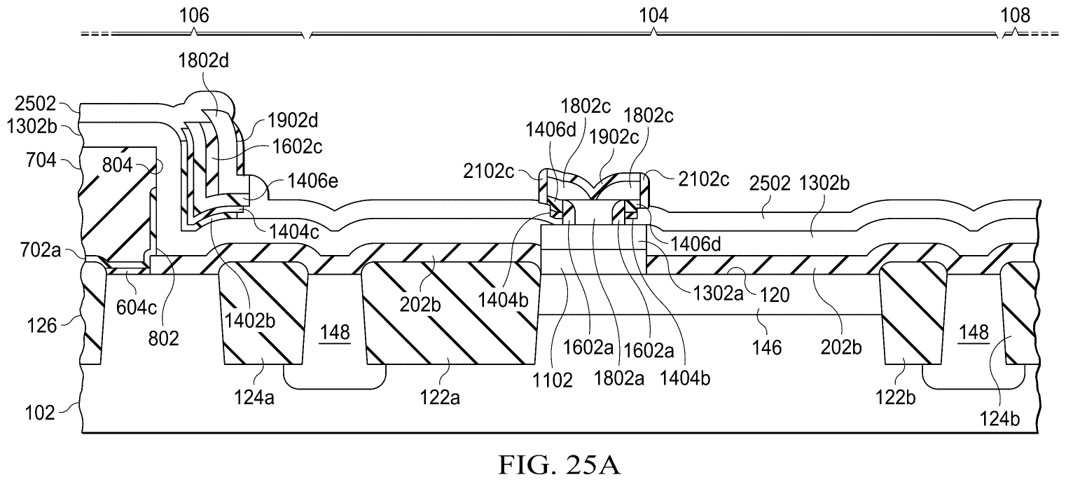

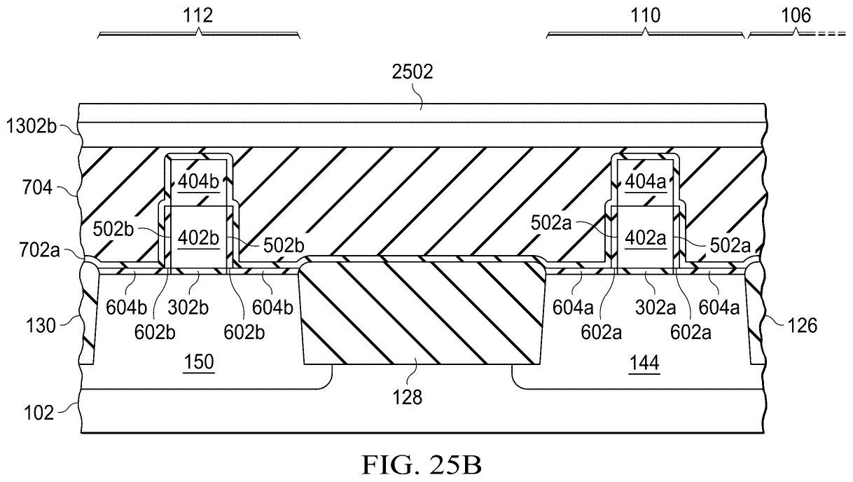

Referring to FIGS. 25A and 25B, a raised base layer 2502 is formed over the base layer 1302. The raised base layer 2502 includes at least a polycrystalline raised base layer on the polycrystalline base layer 1302b. The raised base layer 2502 may include a monocrystalline raised base layer. If the monocrystalline base layer 1302a is exposed by etching the first dielectric spacer layer 1402a, the raised base layer 2502 may include a monocrystalline portion on the monocrystalline base layer 1302a. In some examples, the raised base layer 2502 is or includes a semiconductor layer doped with a p-type dopant (e.g., a same dopant type as the base layer 1302). In some examples, the raised base layer 2502 is or includes silicon. In some examples, the raised base layer 2502 is doped with a p-type dopant with a concentration in a range from 1×10¹⁹ cm⁻³ to 1×10²¹ cm⁻³. The raised base layer 2502 may be epitaxially grown on the base layer 1302. The raised base layer 2502 may be epitaxially grown by a selective epitaxial growth process in some examples. The selective deposition of the raised base layer 2502 forms the raised base layer 2502 conformally on crystalline (e.g., polycrystalline and monocrystalline) surfaces, which include exposed portions of the base layer 1302 (e.g., the polycrystalline base layer 1302b) and the residual polycrystalline emitter spacer 1802d in the first transition region 106. Further, the raised base layer 2502 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

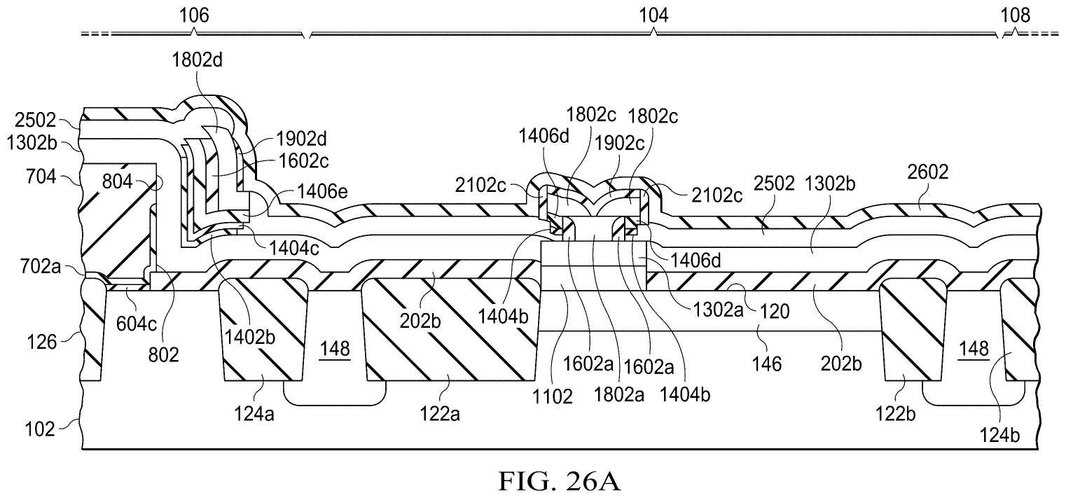

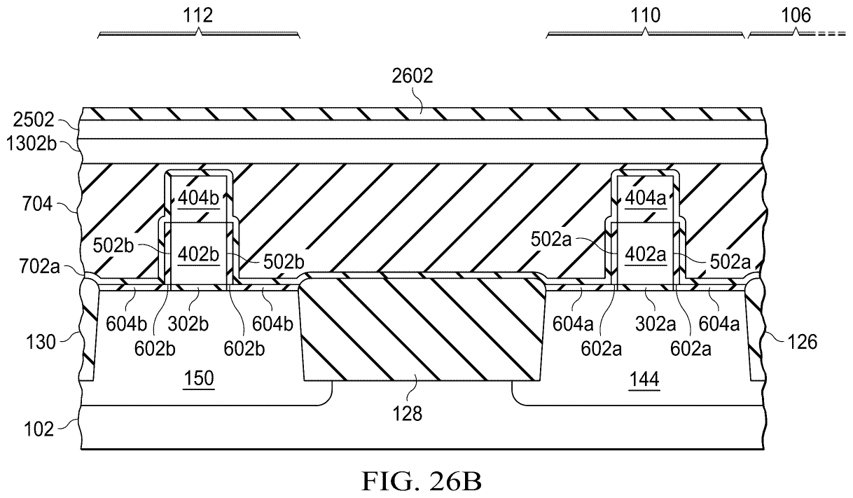

Referring to FIGS. 26A and 26B, a dielectric protective layer 2602 is conformally formed over and along the emitter dielectric cap layer 1902c, the emitter dielectric protective spacers 2102c, and the raised base layer 2502. The dielectric protective layer 2602 is further conformally formed over and along any exposed portions of the residual spacers, such as residual spacer 1902d in the first transition region 106. In some examples, the dielectric protective layer 2602 is silicon oxide (e.g., a TEOS oxide) deposited by CVD, although other dielectric materials and/or other deposition processes may be used in other examples.

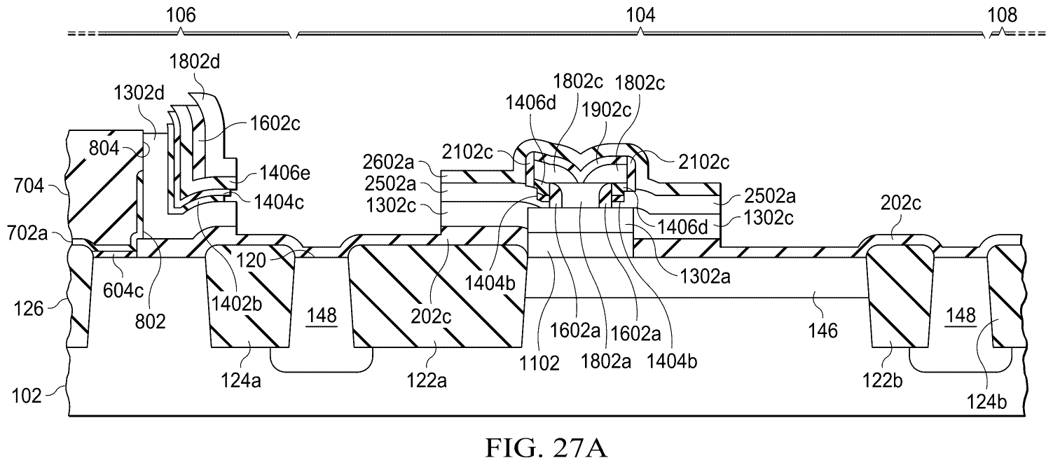

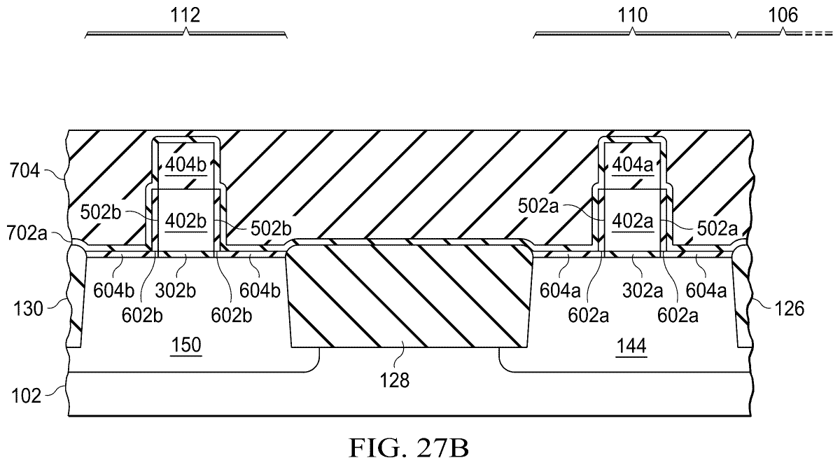

Referring to FIGS. 27A and 27B, the dielectric protective layer 2602, the raised base layer 2502, and the base layer 1302 (e.g., the polycrystalline base layer 1302b) are patterned, and portions of the pedestal dielectric layer 202b are thinned. The raised base layer 2502 and the polycrystalline base layer 1302b are patterned to remain as the raised base layer 2502a and polycrystalline base layer 1302c in the BJT region 104. The dielectric protective layer 2602 is patterned to remain as the dielectric protective layer 2602a over the raised base layer 2502a and the emitter dielectric cap layer 1902c and along sidewalls of the emitter dielectric protective spacers 2102c. The pedestal dielectric layer 202b is thinned in areas where the dielectric protective layer 2602, the raised base layer 2502, and the polycrystalline base layer 1302b are removed and results in the pedestal dielectric layer 202c. The layers 2602, 2502, 1302b, 202b may be patterned or thinned using appropriate photolithography and etch (e.g., RIE) processes. As illustrated, etching the dielectric protective layer 2602 may remove the residual emitter dielectric cap spacer 1902d from the first transition region 106. Patterning the base layer 1302 (e.g., the polycrystalline base layer 1302b) as illustrated permits residual polycrystalline base spacer 1302d to remain on the sidewalls 802, 804 in the first transition region 106. In some instances, the etch process may also etch (e.g., reduce) other residual spacers in the first transition region 106, which is not illustrated.

In subsequent processing for forming the nFET and the pFET, a lower thermal budget may be implemented. The lower thermal budget may mitigate against relaxation of the monocrystalline base layer 1302a when the monocrystalline base layer 1302a is a material dissimilar from the collector layer 1102. The lower thermal budget may also mitigate against diffusion of dopants between the collector layer 1102, base layer 1302, raised base layer 2502a, and/or emitter layer 1802. Examples of such thermal processing with a lower thermal budget are provided below.

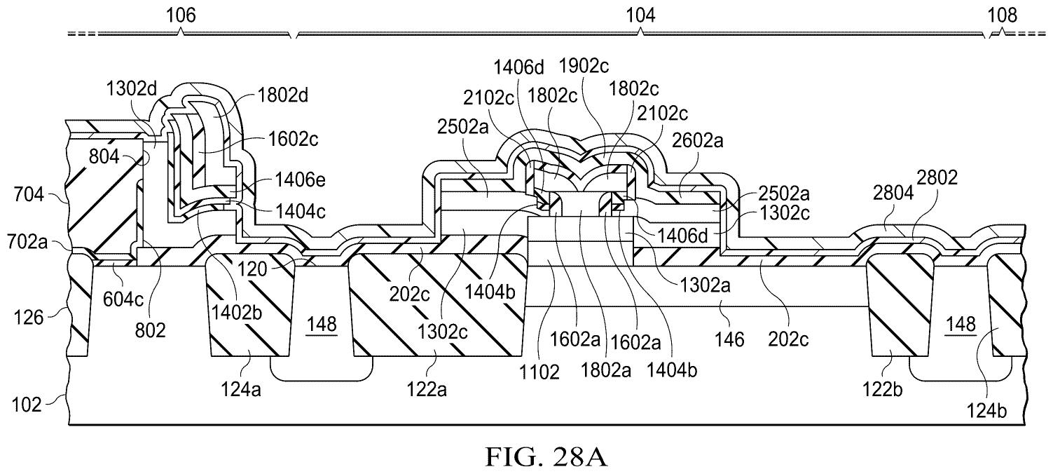

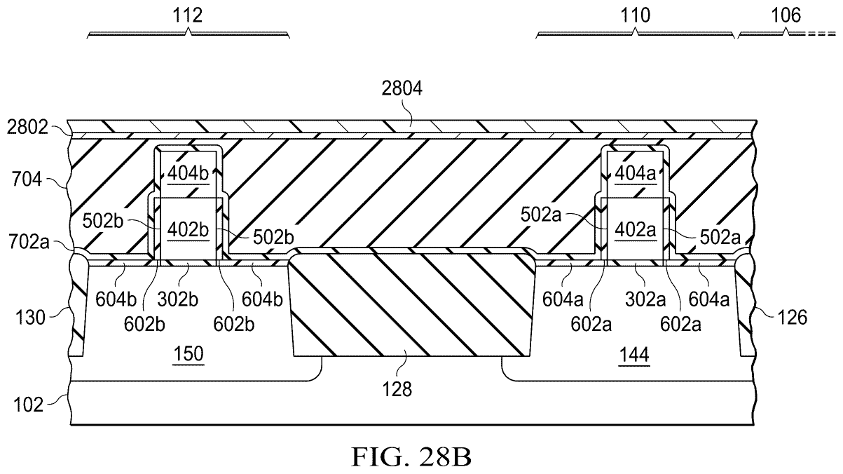

Referring to FIGS. 28A and 28B, a first hardmask layer 2802 is conformally formed over the semiconductor substrate 102, and a second hardmask layer 2804 is conformally formed over the first hardmask layer 2802. More specifically, the first hardmask layer 2802 is conformally formed over the isolation structure 122, the upper surface 120 of the semiconductor substrate 102, the pedestal dielectric layer 202c, and the dielectric protective layer 2602a and along sidewalls of the polycrystalline base layer 1302c and raised base layer 2502a in the BJT region 104. The first hardmask layer 2802 is conformally formed over the residual spacers 1302d, 1402b, 1404c, 1406e, 1602c, 1802d in the first transition region 106 and over the fill material 704 in the first transition region 106, pFET region 110, and nFET region 112. In some examples, the first hardmask layer 2802 is or includes silicon nitride deposited by CVD, although other hardmask (e.g., dielectric) materials and/or other deposition processes may be used in other examples. In some examples, the second hardmask layer 2804 is or includes silicon oxide deposited by CVD, although other hardmask (e.g., dielectric) materials and/or other deposition processes may be used in other examples.

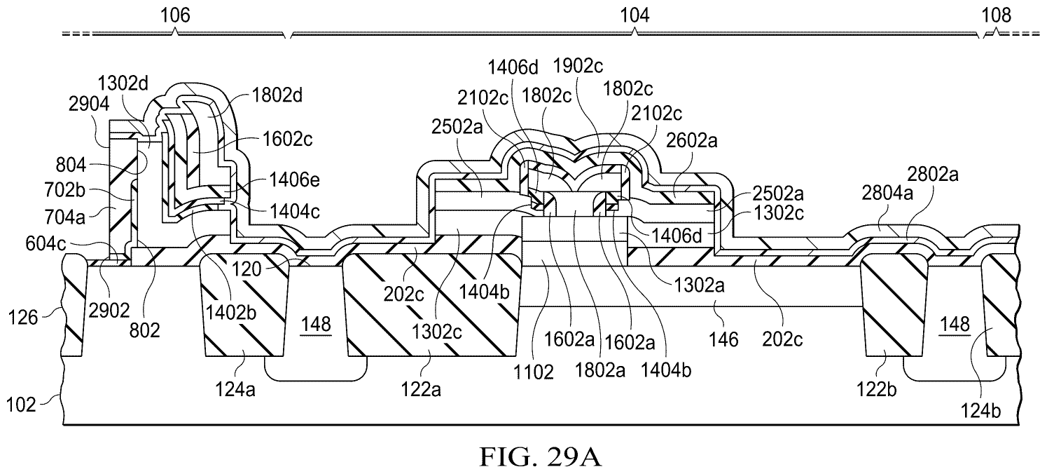

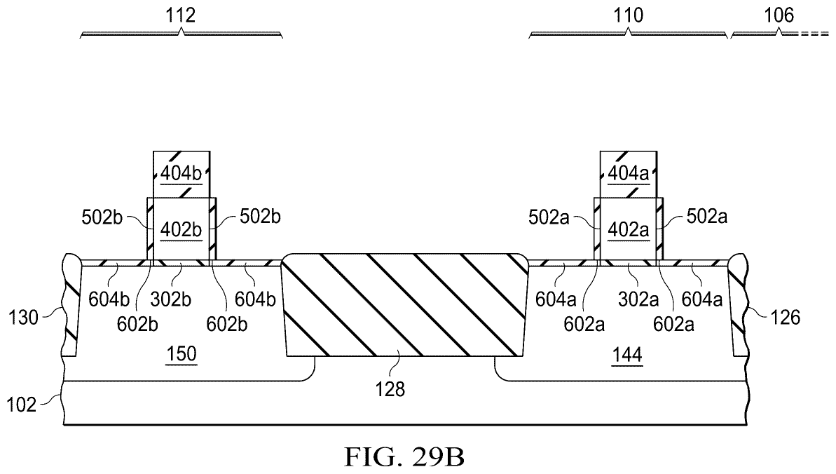

Referring to FIGS. 29A and 29B, the fill material 704 and the etch stop layer 702a are at least partially removed. As illustrated, residual fill material 704a and etch stop layer 702b remain in the first transition region 106 and are removed from the pFET region 110 and nFET region 112. The fill material 704 and etch stop layer 702a are removed from the lateral sides of the gate electrodes 402a, 402b in the pFET region 110 and nFET region 112 (e.g., removed from the reoxidation layers 602a, 602b on the sidewalls 502a, 502b). Additionally, the first hardmask layer 2802 and the second hardmask layer 2804 are removed where the fill material 704 and etch stop layer 702b are removed resulting in the first hardmask layer 2802a and the second hardmask layer 2804a in the first transition region 106 and BJT region 104. Removing the fill material 704 and the etch stop layer 702b from the pFET region 110 and nFET region 112, as illustrated, forms sidewalls 2902, 2904 of the etch stop layer 702b and residual fill material 704a, respectively, that remain in the first transition region 106. The sidewalls 2902, 2904 face the pFET region 110 and nFET region 112 (e.g., face the gate electrodes 402a, 402b) and face opposite from the sidewalls 802, 804 of the etch stop layer 702b and residual fill material 704a, respectively. The fill material 704 and the etch stop layer 702b may be removed using appropriate photolithography and etch (e.g., RIE) processes.

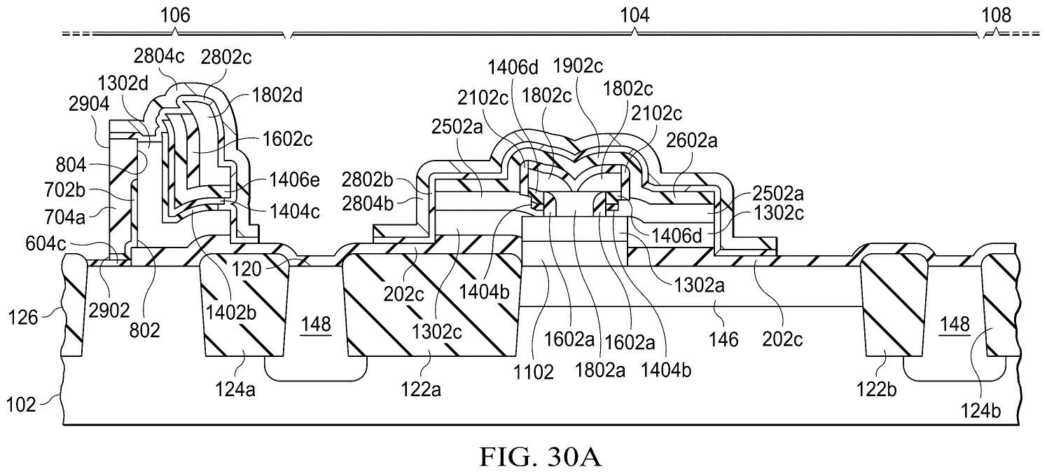

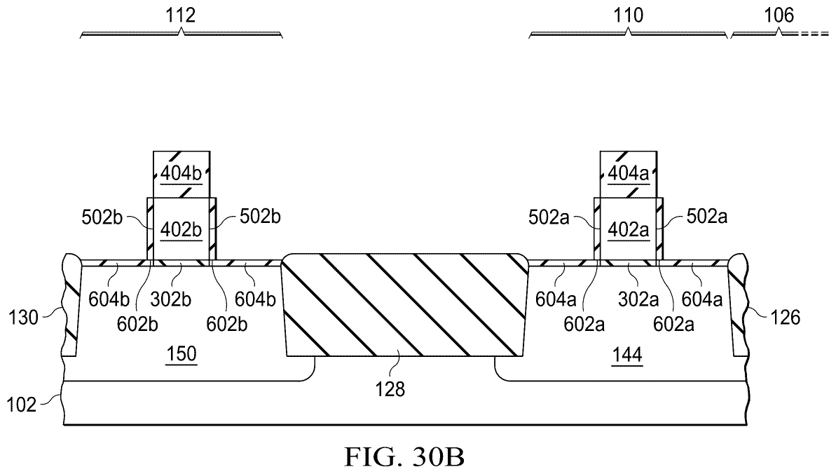

Referring to FIGS. 30A and 30B, the first hardmask layer 2802a and the second hardmask layer 2804a are patterned into first hardmask layers 2802b, 2802c and second hardmask layers 2804b, 2804c. The first hardmask layer 2802b and second hardmask layer 2804b are over the dielectric protective layer 2602a and along sidewalls of the polycrystalline base layer 1302c and the raised base layer 2502a. The first hardmask layer 2802b and second hardmask layer 2804b further extend laterally away from the polycrystalline base layer 1302c over the pedestal dielectric layer 202c in the BJT region 104. The first hardmask layer 2802b and second hardmask layer 2804b are over and along sidewalls of the residual spacers 1302d, 1402b, 1404c, 1406e, 1602c, 1802d and the residual fill material 704a in the first transition region 106. Respective portions of the first hardmask layer 2802a and the second hardmask layer 2804a are removed by the patterning from over at least a portion of respective thinned portions of the pedestal dielectric layer 202c over the n-type doped sub-collector diffusion region 146 and the p-type doped well 148. The first hardmask layer 2802a and the second hardmask layer 2804a may be patterned using appropriate photolithography and etch processes. For example, a mask (e.g., a photoresist) may mask the first transition region 106 from where the hardmask layers 2802c, 2804c remain into the pFET region 110 and the nFET region 112, and may mask where the hardmask layers 2802b, 2804b remain in the BJT region 104 during an etch process.

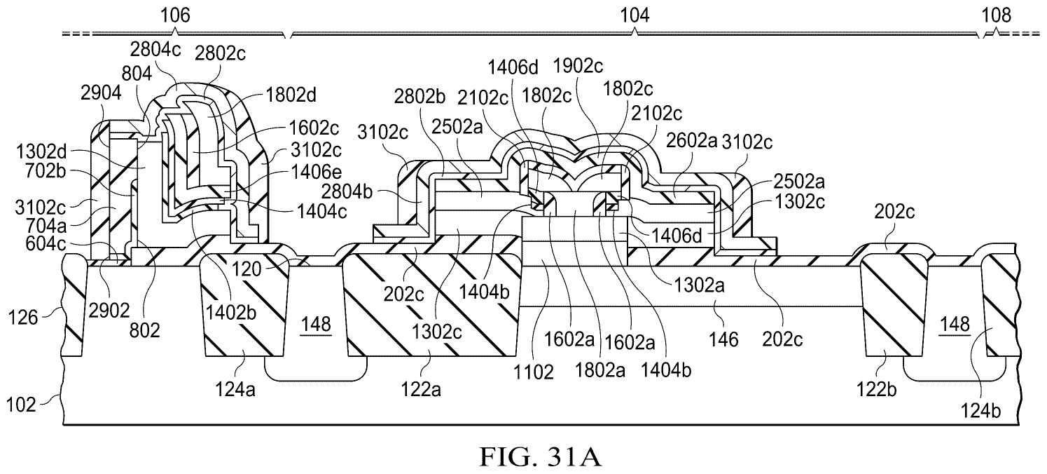

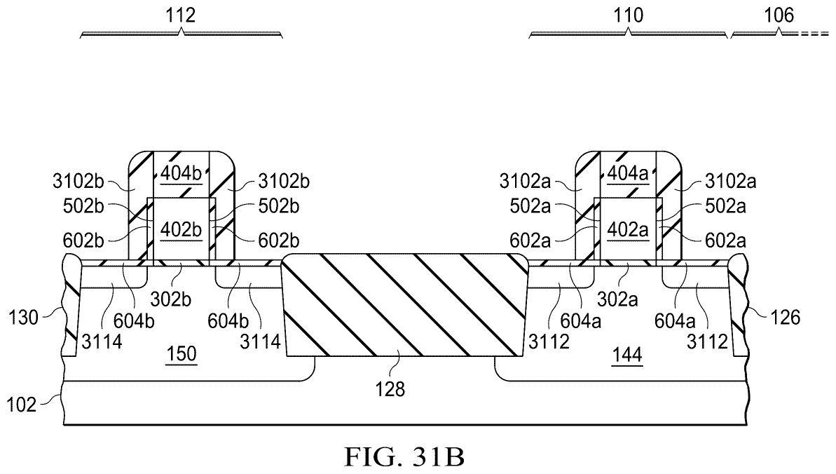

Referring to FIGS. 31A and 31B, first gate dielectric spacers 3102a, 3102b are formed along sidewalls 502a, 502b of the gate electrodes 402a, 402b (e.g., on the reoxidation layers 602a, 602b). The first gate dielectric spacers 3102a, 3102b may be formed by depositing a layer of the material of the first gate dielectric spacers 3102a, 3102b conformally over the semiconductor substrate 102 and anisotropically etching (e.g., by RIE) the layer such that the first gate dielectric spacers 3102a, 3102b remain. The material of the first gate dielectric spacers 3102a, 3102b may be any appropriate dielectric material, such as silicon nitride, silicon oxynitride, silicon carbon nitride, the like, or a combination thereof. The layer may be deposited by CVD, PECVD, ALD, or the like. The formation of the first gate dielectric spacers 3102a, 3102b may further form residual dielectric spacers 3102c, e.g., on vertical surfaces of the second hardmask layers 2804b, 2804c and the sidewalls 2902, 2904.

P-type lightly doped drain regions (LDDs) 3112 and n-type LDDs 3114 are formed in the semiconductor substrate 102 in the pFET region 110 and the nFET region 112, respectively. The p-type LDDs 3112 are in the semiconductor substrate 102 on laterally opposing sides of the gate electrode 402a, and the n-type LDDs 3114 are in the semiconductor substrate 102 on laterally opposing sides of the gate electrode 402b. The p-type LDDs 3112 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 3114 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 3112 is greater than the concentration of the n-type dopant of the n-type doped well 144, and a concentration of the n-type dopant of the n-type LDDs 3114 is greater than the concentration of the p-type dopant of the p-type doped well 150. In some examples, the p-type LDDs 3112 are doped with a p-type dopant with a concentration in a range from 1×10¹⁹ cm⁻³ to 1×10²¹ cm⁻³, and the n-type LDDs 3114 are doped with an n-type dopant with a concentration in a range from 1×10¹⁹ cm⁻³ to 1×10²¹ cm⁻³. Other doping concentrations may be implemented.

After performing implantation(s) to form the p-type LDDs 3112 and the n-type LDDs 3114, an activation anneal may be performed. In some examples with a lower thermal budget, the activation anneal includes a laser anneal following the first implantation (e.g., of n-type or p-type dopants) and a spike anneal reaching 930° C. or less following the second implantation (e.g., of the other of the n-type or p-type dopants).

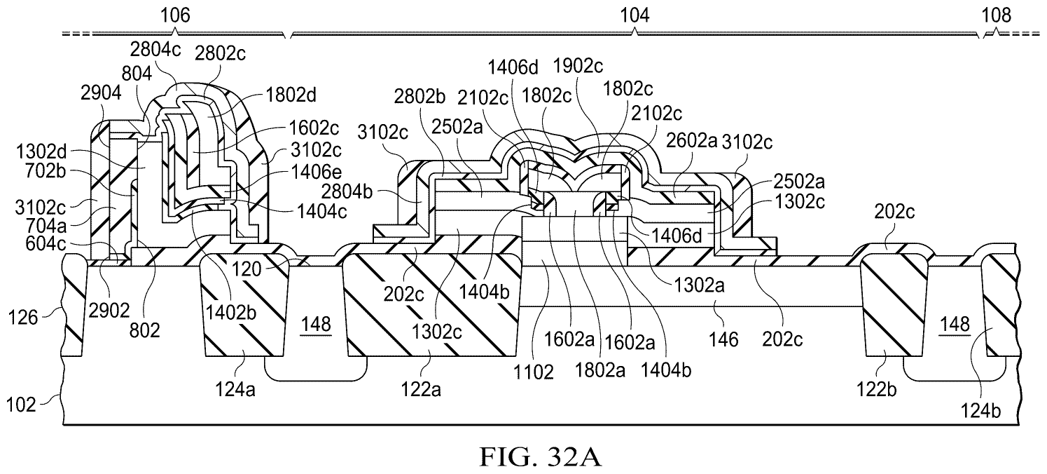

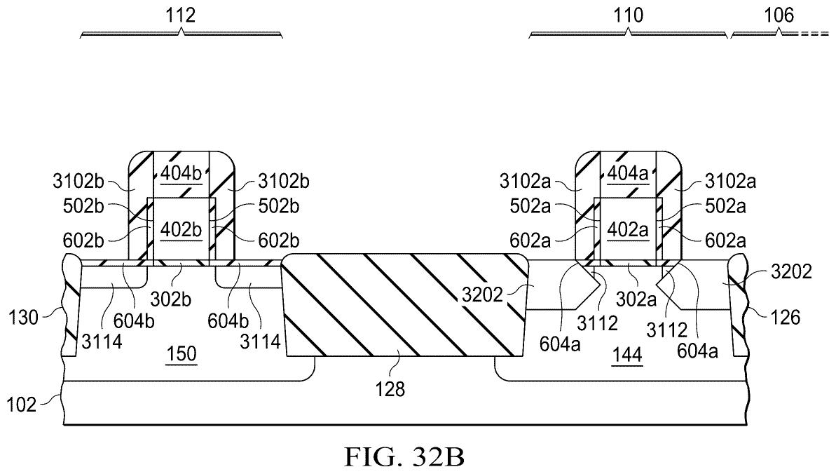

Referring to FIGS. 32A and 32B, embedded stressors 3202 are formed in the semiconductor substrate 102 in the pFET region 110. To form the embedded stressors 3202, respective recesses are formed in the semiconductor substrate 102. To form the recesses, a conformal hardmask layer (not illustrated) is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching (e.g., RIE) processes. Then, stressor recesses are formed in the semiconductor substrate 102 in the pFET region 110. The stressor recesses are etched in the semiconductor substrate 102 where the embedded stressors are to be formed. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 3202 are then formed in the stressor recesses. The embedded stressors 3202 may be formed using a selective epitaxial growth process. The embedded stressors 3202 may be formed using MOCVD, molecular beam epitaxy (MBE), LPCVD, or another epitaxy process. In some examples, the embedded stressors 3202 are a semiconductor material that causes a compressive stress in the channel region in the semiconductor substrate 102 under the gate electrode 402a. For example, when the semiconductor substrate 102 is silicon, the embedded stressors 3202 may be or include silicon germanium.

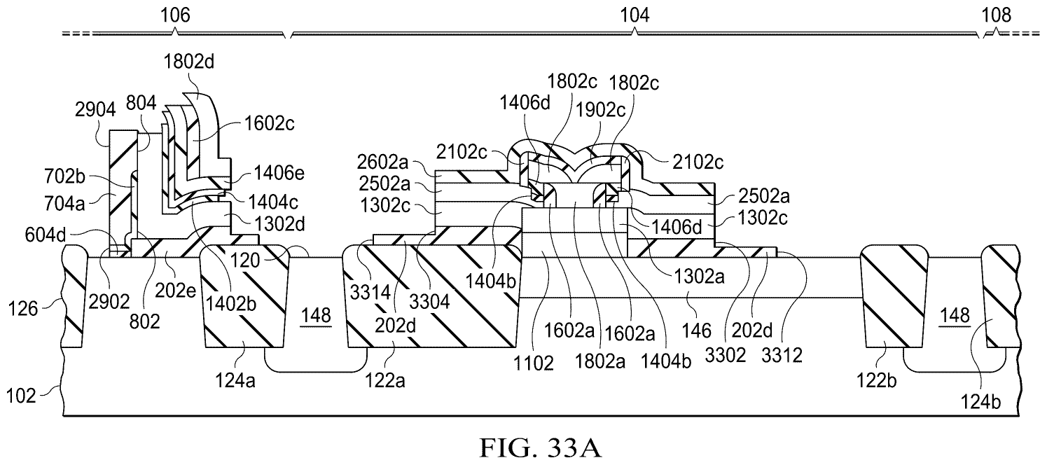

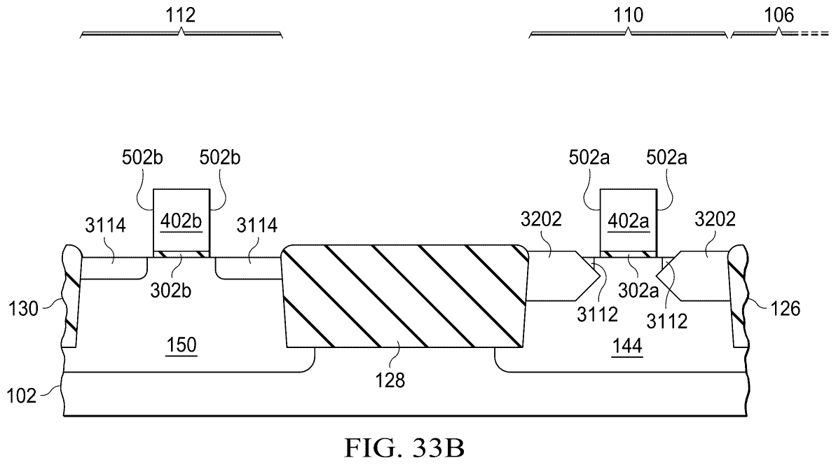

Referring to FIGS. 33A and 33B, the conformal hardmask layer for forming the embedded stressors 3202, the first gate dielectric spacers 3102a, 3102b, the residual dielectric spacers 3102c, the hardmask layers 404a, 404b, the reoxidation layers 602a, 602b, 604a, 604b, the second hardmask layer 2804a, and the first hardmask layer 2802a are removed, and the pedestal dielectric layer 202c is patterned into a pedestal dielectric layer 202d and a residual pedestal dielectric layer 202e. These layers and spacers may be removed or patterned by etch processes selective to the material of the respective layers and spacers, which may be wet or dry etch processes and may be isotropic. As an example, when the conformal hardmask layer, the first gate dielectric spacers 3102a, 3102b, the residual dielectric spacers 3102c, the hardmask layers 404a, 404b, and the first hardmask layers 2802b, 2802c are silicon nitride, and the reoxidation layers 602a, 602b, 604a, 604b, the second hardmask layers 2804b, 2804c, and the pedestal dielectric layer 202c are silicon oxide, wet etch processes including phosphoric acid followed by hydrofluoric acid followed by phosphoric acid may be implemented. The first wet etch including phosphoric acid may remove the conformal hardmask layer, the first gate dielectric spacers 3102a, 3102b, the residual dielectric spacers 3102c, and at least a part of the hardmask layers 404a, 404b. The wet etch including hydrofluoric acid may then remove any remaining second hardmask layers 2804b, 2804c (a portion of which may have been previously removed by cleaning processes), the reoxidation layers 602a, 602b, 604a, 604b (which may further remove any exposed portion of the reoxidation layer 604c to form the reoxidation layer 604d), and exposed portions of the pedestal dielectric layer 202c. During the wet etch including hydrofluoric acid, the first hardmask layers 2802b, 2802c may mask the pedestal dielectric layer 202c such that respective portions under the first hardmask layers 2802b, 2802c remain as the pedestal dielectric layer 202d and the residual pedestal dielectric layer 202e. The second wet etch including phosphoric acid may then remove the first hardmask layers 2802b, 2802c and any remaining hardmask layers 404a, 404b. In some examples, removal of the first gate dielectric spacers 3102a, 3102b and the reoxidation layers 602a, 602b may be omitted.

The pedestal dielectric layer 202d is in the BJT region 104 and underlies the base layer 1302. The portion of the pedestal dielectric layer 202d directly underlying the base layer 1302 has a first thickness. The pedestal dielectric layer 202d has sidewalls 3302, 3304 that align with respective sidewalls of the base layer 1302. The pedestal dielectric layer 202d has the first thickness laterally between the sidewalls 3302, 3304. The pedestal dielectric layer 202d extends laterally beyond the base layer 1302 (e.g., the polycrystalline base layer 1302c). For example, the pedestal dielectric layer 202d extends on the upper surface 120 of the semiconductor substrate 102 over the n-type doped sub-collector diffusion region 146 and laterally away from the polycrystalline base layer 1302c to a sidewall 3312 over the n-type doped sub-collector diffusion region 146, which is laterally away from the sidewall 3302. Additionally, the pedestal dielectric layer 202c extends on the first portion 122a of the isolation structure 122 laterally away from the polycrystalline base layer 1302c to a sidewall 3314 over the first portion 122a of the isolation structure 122, which is laterally away from the sidewall 3312. The pedestal dielectric layer 202d has a second thickness laterally between the sidewalls 3302, 3312 and laterally between the sidewalls 3304, 3314, which is less than the first thickness laterally between the sidewalls 3302, 3304. The pedestal dielectric layer 202e is in the first transition region 106 and underlies the residual polycrystalline base spacer 1302d.

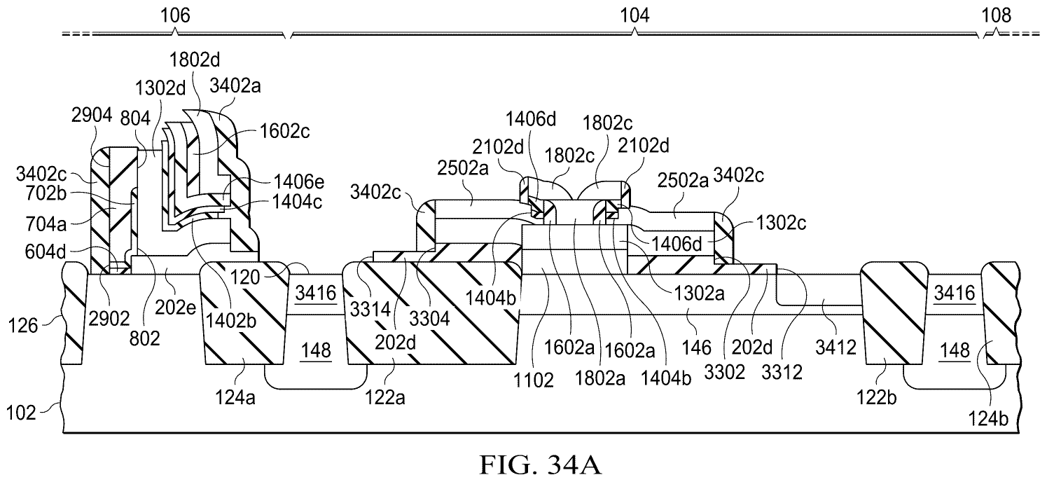

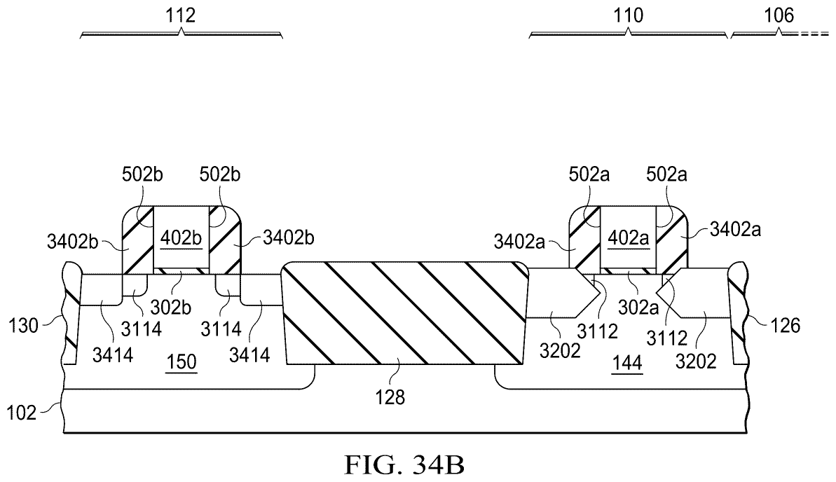

Referring to FIGS. 34A and 34B, second gate dielectric spacers 3402a, 3402b are formed along the sidewalls 502a, 502b of the gate electrodes 402a, 402b, respectively. The second gate dielectric spacers 3402a, 3402b may be formed by depositing a layer of the material of the second gate dielectric spacers 3402a, 3402b conformally over the semiconductor substrate 102 and anisotropically etching (e.g., by RIE) the layer such that the second gate dielectric spacers 3402a, 3402b remain. The material of the second gate dielectric spacers 3402a, 3402b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3402a, 3402b may further form residual dielectric spacers 3402c on sidewalls of components in the BJT region 104 and the first transition region 106.

The etch process for forming the second gate dielectric spacers 3402a, 3402b may include a cleaning process following, e.g., the anisotropic etch. The cleaning process may include an etchant that removes the dielectric protective layer 2602a and the emitter dielectric cap layer 1902c. For example, when the dielectric protective layer 2602a and the emitter dielectric cap layer 1902c are silicon oxide, the cleaning process may include hydrofluoric acid that removes the dielectric protective layer 2602a and the emitter dielectric cap layer 1902c. In some examples, the emitter dielectric protective spacers 2102c may be removed or reduced to form emitter dielectric protective spacers 2102d by the cleaning process.

A stress memorization technique may be implemented, such as in the nFET region 112. A stressor dielectric layer is formed over the semiconductor substrate 102, gate electrode 402b, and second gate dielectric spacers 3402b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process may be or include a millisecond laser anneal for dopant activation and a spike rapid thermal anneal (RTA) with reduced thermal budget. A spike RTA may be at peak temperature for approximately 1 second and rapidly decrease in temperature to minimize dopant diffusion. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

An n-type collector contact region 3412, n-type source/drain (NSD) regions 3414, p-type source/drain (PSD) regions, and a p-type guardring contact region 3416 are formed in the semiconductor substrate 102. The n-type collector contact region 3412 is formed in the BJT region 104 in the n-type doped sub-collector diffusion region 146 in the semiconductor substrate 102. The n-type collector contact region 3412 is laterally between the pedestal dielectric layer 202c and the second portion 122b of the isolation structure 122. The NSD regions 3414 are formed in the nFET region 112 in the p-type doped well 150 in the semiconductor substrate 102. The NSD regions 3414 are on opposing lateral sides of the gate electrode 402b with the n-type LDDs 3114 therebetween. The PSD regions are formed in the pFET region 110 and may be formed in the embedded stressors 3202 and/or may further extend below the embedded stressors 3202 into the n-type doped well 144 in the semiconductor substrate 102. The PSD regions are on opposing lateral sides of the gate electrode 402a with the p-type LDDs 3112 therebetween. The p-type guardring contact region 3416 is formed in the BJT region 104 in the p-type doped well 148 in the semiconductor substrate 102. The p-type guardring contact region 3416 is laterally between the isolation structures 122, 124.

An implantation is performed to form the n-type collector contact region 3412 and the NSD regions 3414. The n-type collector contact region 3412 and the NSD regions 3414 may be formed by masking (e.g., by a photoresist using photolithography) the pFET region 110 and the base layer 1302, raised base layer 2502a, and emitter layer 1802 in the BJT region 104 and implanting an n-type dopant into the semiconductor substrate 102 in the nFET region 112 and exposed portion of the BJT region 104. An implantation is performed to form the PSD regions and the p-type guardring contact region 3416. The PSD regions and the p-type guardring contact region 3416 may be formed by masking (e.g., by a photoresist using photolithography) the BJT region 104, except the p-type doped well 148, and the nFET region 112 and implanting a p-type dopant into the semiconductor substrate 102 in the pFET region 110 and in the p-type doped well 148. Simultaneously with implanting the PSD regions and the p-type guardring contact region 3416, the raised base layer 2502a and/or base layer 1302 may be implanted. An area of the raised base layer 2502a may be exposed by the mask during the implantation of the PSD regions and the p-type guardring contact region 3416 so as to also implant p-type dopant into the raised base layer 2502a and/or base layer 1302.

A concentration of the n-type dopant of the n-type collector contact region 3412 is greater than the concentration of the n-type dopant of the n-type doped sub-collector diffusion region 146. A concentration of the n-type dopant of the NSD regions 3414 is greater than the concentration of the n-type dopant of the n-type LDDs 3114 and the concentration of the p-type dopant of the p-type doped well 150. A concentration of the p-type dopant of the PSD regions is greater than the concentration of the p-type dopant of the p-type LDDs 3112 and the concentration of the n-type dopant of the n-type doped well 144. A concentration of the p-type guardring contact region 3416 is greater than the concentration of the p-type dopant of the p-type doped well 148. In some examples, the n-type collector contact region 3412 and the NSD regions 3414 are doped with an n-type dopant with a concentration in a range from 1×10²⁰ cm⁻³ to 1×10²¹ cm⁻³, and the PSD regions and the p-type guardring contact region 3416 are doped with a p-type dopant with a concentration in a range from 1×10²⁰ cm⁻³ to 1×10²¹ cm⁻³. Other doping concentrations may be implemented.

After performing the implantations to form the n-type collector contact region 3412, NSD regions 3414, PSD regions, and p-type guardring contact region 3416, an activation anneal may be performed. In some examples with a lower thermal budget, the activation anneal includes a laser anneal following the first implantation (e.g., of n-type or p-type dopants) and a spike anneal reaching 1,010° C. or less following the second implantation (e.g., of the other of the n-type or p-type dopants).

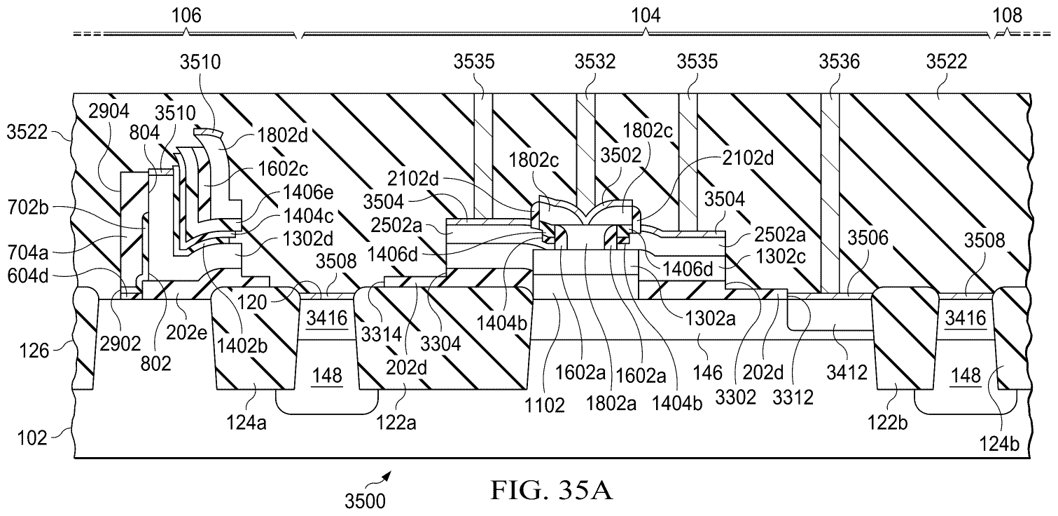

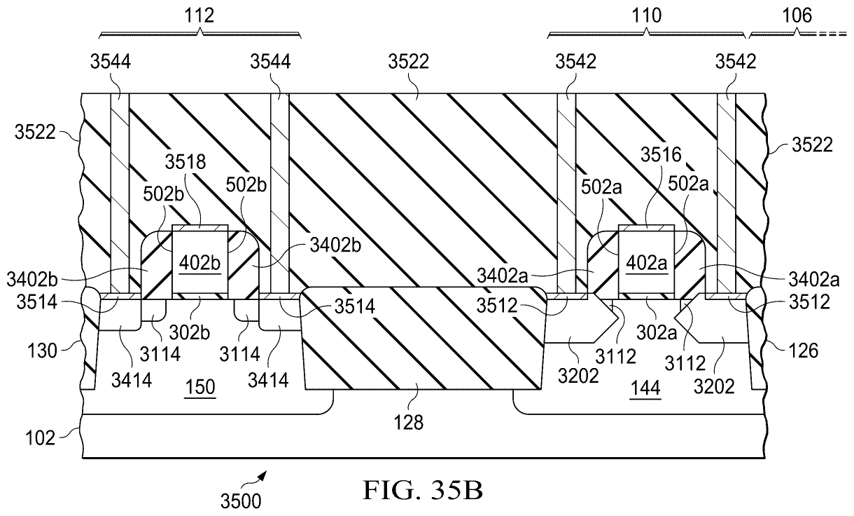

Referring to FIGS. 35A and 35B, metal-semiconductor compound 3502, 3504, 3506, 3508, 3510, 3512, 3514, 3516, 3518 are formed. The metal-semiconductor compound 3502 is on the emitter layer 1802 (e.g., the polycrystalline emitter layer 1802c and/or monocrystalline emitter layer 1802a). The metal-semiconductor compound 3504 is on the raised base layer 2502a. The metal-semiconductor compound 3506 is on the upper surface 120 of the semiconductor substrate 102 at the n-type collector contact region 3412. The metal-semiconductor compound 3508 is on the upper surface 120 of the semiconductor substrate 102 at the p-type doped well 148. The metal-semiconductor compound 3510 is on exposed surfaces of the residual polycrystalline base spacer 1302d and the residual polycrystalline emitter spacer 1802d in the first transition region 106. The metal-semiconductor compound 3512 are on the embedded stressors 3202. The metal-semiconductor compound 3514 are on the NSD regions 3414 in the semiconductor substrate 102. The metal-semiconductor compound 3516, 3518 are on the gate electrodes 402a, 402b, respectively. The metal-semiconductor compound 3502-3518 may be a silicide (e.g., NiSix, TiSix, CoSix, PtSix), a germanicide, or the like.

The metal-semiconductor compound 3502-3518 may be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 1802 (e.g., polycrystalline emitter layer 1802c and/or monocrystalline emitter layer 1802a), the semiconductor material of the raised base layer 2502a, the semiconductor material of the semiconductor substrate 102, the semiconductor material of the embedded stressors 3202, and the semiconductor material (e.g., silicon, such as polysilicon) of the gate electrodes 402a, 402b. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound, in some examples, the residual dielectric spacers 3402c may be removed. Further, in some examples, the second gate dielectric spacers 3402a, 3402b may be removed simultaneously with the residual dielectric spacers 3402c. In some examples, an appropriate etch process, such as a wet or dry etch and/or isotropic etch, may be implemented. If the second gate dielectric spacers 3402a, 3402b are to remain, the pFET region 110 and nFET region 112 may be masked, such as by a photoresist using photolithography, during the etch process.

A dielectric layer 3522 is formed over the semiconductor substrate 102, and contacts 3532, 3534, 3536, 3542, 3544 are formed through the dielectric layer 3522. The dielectric layer 3522 may include one or more dielectric sub-layers. For example, the dielectric layer 3522 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 3522 may be or include a pre-metal dielectric (PMD), an inter-layer dielectric (ILD), or the like. The dielectric layer 3522 may be deposited using CVD, PECVD, ALD, or the like. The dielectric layer 3522 may be planarized, such as by a CMP.

The contacts 3532, 3534, 3536, 3542, 3544 extend through the dielectric layer 3522 and contact respective metal-semiconductor compound 3502, 3504, 3506, 3512, 3514. The contacts 3532, 3534, 3536, 3542, 3544 may each include one or more barrier and/or adhesion layers (e.g., titanium nitride (TiN), tantalum nitride (TaN), the like, or a combination thereof) conformally in a respective opening through the dielectric layer 3522, and a fill metal (e.g., tungsten (W), copper (Cu), aluminum (Al), the like, or a combination thereof) over and/or on the barrier and/or adhesion layer(s).

To form the contacts 3532, 3534, 3536, 3542, 3544, respective openings may be formed through the dielectric layer 3522 to the metal-semiconductor compound 3502, 3504, 3506, 3512, 3514 using appropriate photolithography and etching processes. A metal(s) of the contacts 3532, 3534, 3536, 3542, 3544 are deposited in the openings through the dielectric layer 3522. The metal(s) may be deposited using an appropriate deposition process(es), such as CVD, PVD, or the like. Any excess metal(s) may be removed, such as by a CMP and/or by patterning using photolithography and etch processes.

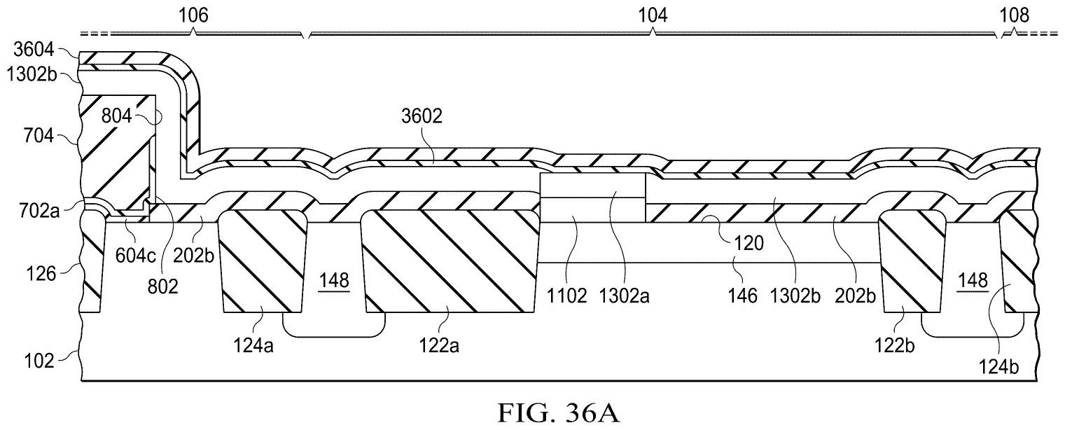

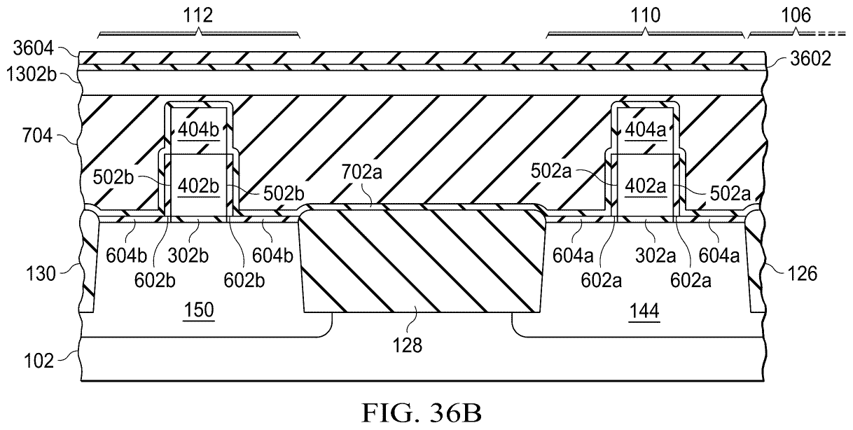

FIGS. 36A and 36B through FIGS. 42A and 42B are respective cross-sectional views of a semiconductor device in intermediate stages of manufacturing according to some examples. Semiconductor processing proceeds as described above with respect to FIGS. 1A and 1B through FIGS. 13A and 13B.

With reference to FIGS. 36A and 36B, a first dielectric spacer layer 3602 is formed conformally over the base layer 1302, and a second dielectric spacer layer 3604 is formed conformally over the first dielectric spacer layer 3602. In some examples, the second dielectric spacer layer 3604 is a dielectric material different from the dielectric material of the first dielectric spacer layer 3602. In some examples, the first dielectric spacer layer 3602 is silicon oxide (e.g., a TEOS oxide), and the second dielectric spacer layer 3604 is silicon nitride. The dielectric spacer layers 3602, 3604 may be deposited by CVD. Other dielectric materials and/or other deposition processes may be used in other examples.

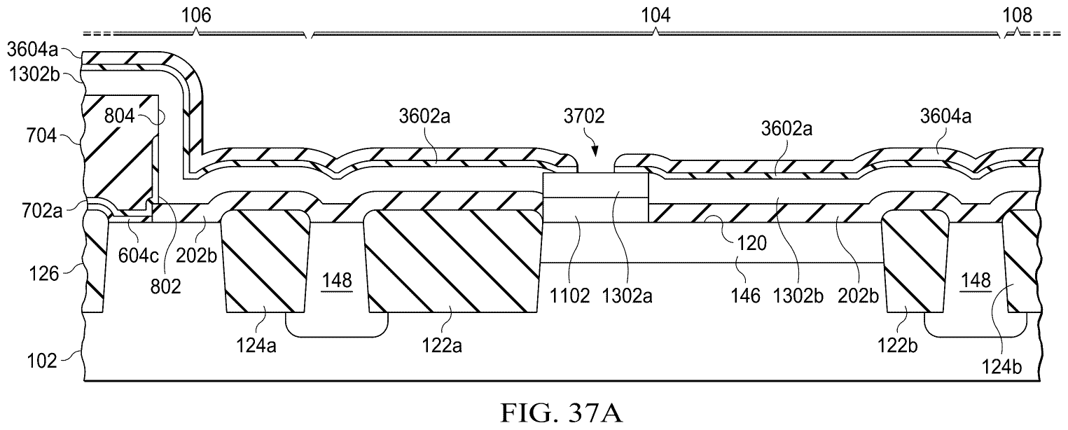

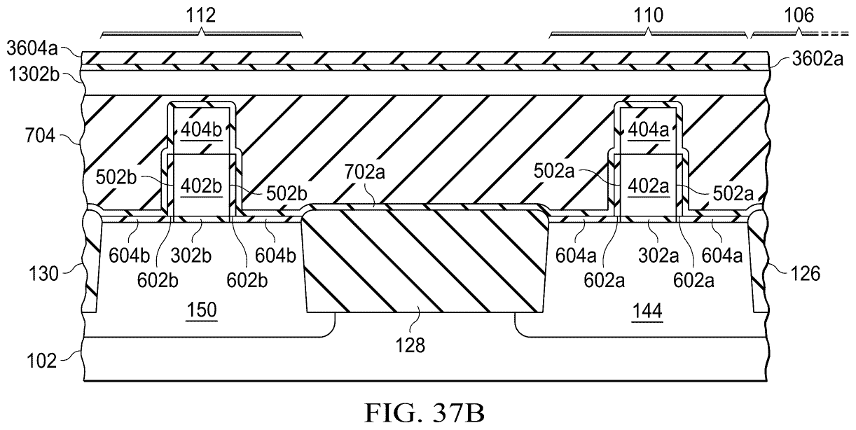

Referring to FIGS. 37A and 37B, the dielectric spacer layers 3602, 3604 are etched to form an emitter opening 3702 through the first dielectric spacer layer 3602a and the second dielectric spacer layer 3604a. The monocrystalline base layer 1302a (of the base layer 1302) is exposed through the emitter opening 3702. The emitter opening 3702 is in the BJT region 104. The dielectric spacer layers 3602, 3604 may be patterned using appropriate photolithography and etch (e.g., RIE) processes.

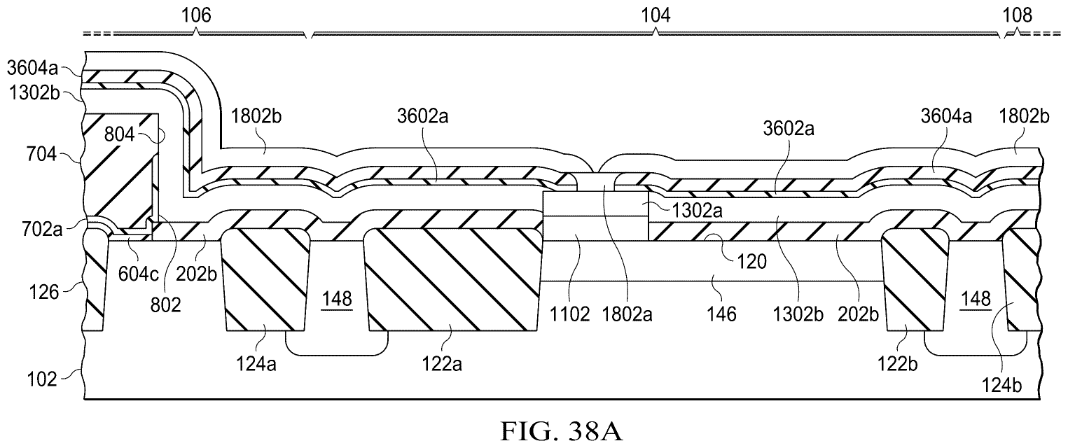

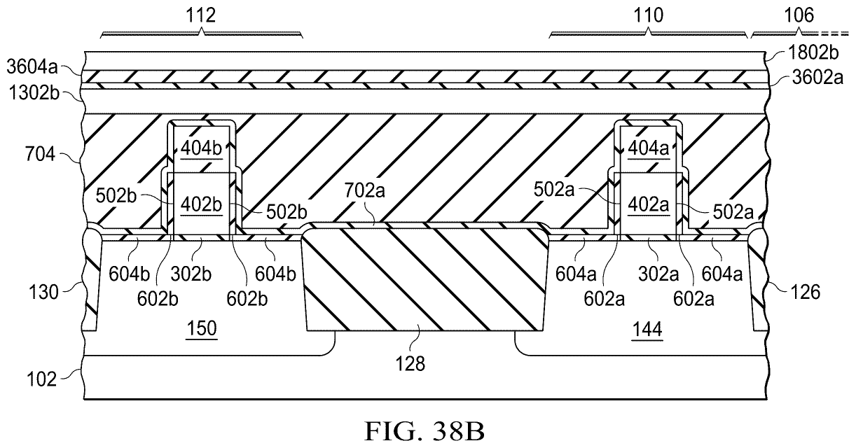

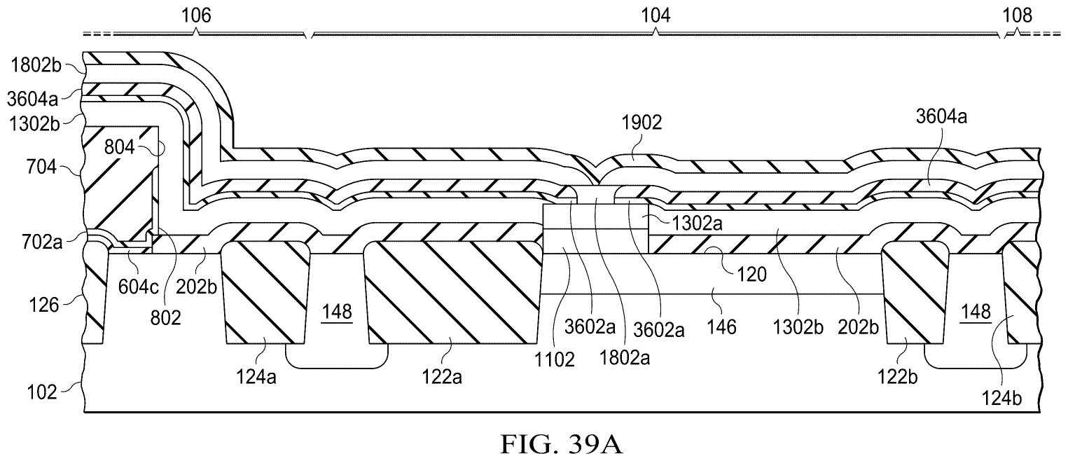

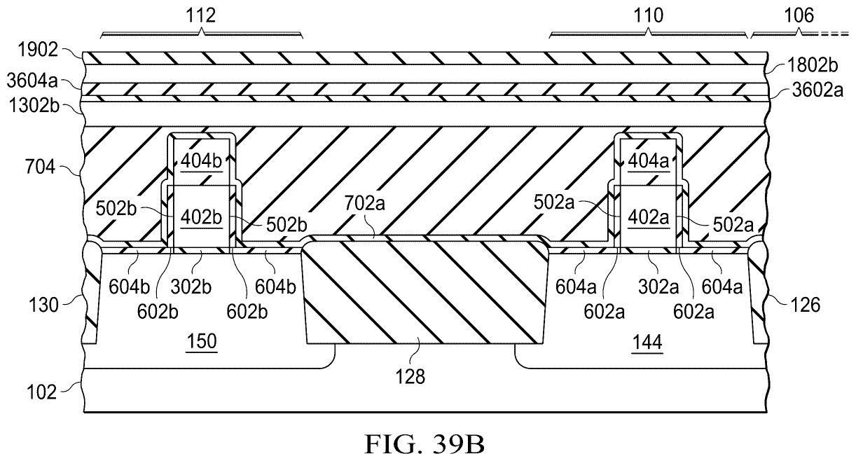

Referring to FIGS. 38A and 38B, an emitter layer 1802 is formed over the base layer 1302 (e.g., on the monocrystalline base layer 1302a) like described with respect to FIGS. 18A and 18B. The emitter layer 1802 may be epitaxially grown on the base layer 1302 (e.g., the monocrystalline base layer 1302a) exposed through the emitter opening 3702 and on the second dielectric spacer layer 3604a. Referring to FIGS. 39A and 39B, an emitter dielectric cap layer 1902 is conformally formed over the emitter layer 1802 like described with respect to FIGS. 19A and 19B.

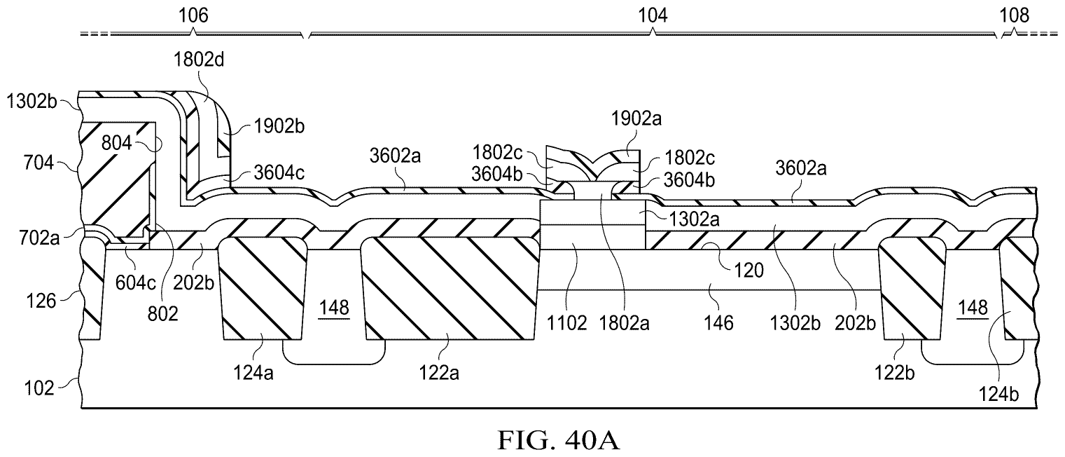

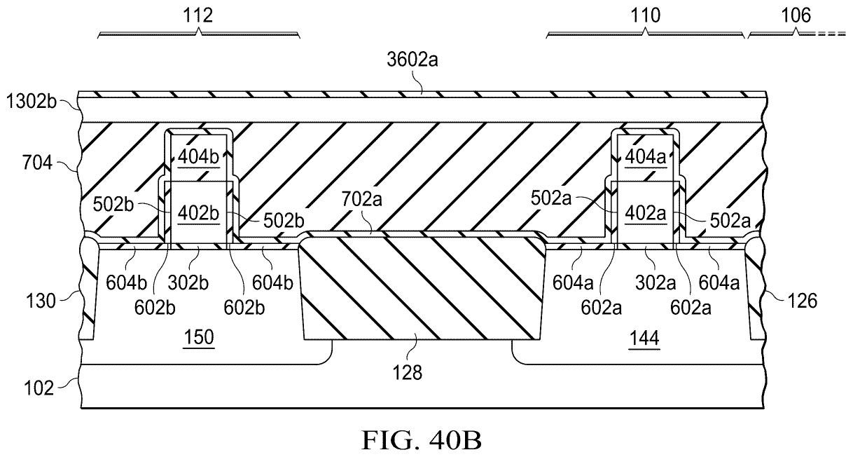

Referring to FIGS. 40A and 40B, the emitter dielectric cap layer 1902, the polycrystalline emitter layer 1802b, and the second dielectric spacer layer 3604a are etched to form the emitter dielectric cap layer 1902a, polycrystalline emitter layer 1802c, and second dielectric spacer 3604b. The layers 1902, 1802b, 3604a may be patterned using appropriate photolithography and etch (e.g., RIE) processes. Patterning the emitter dielectric cap layer 1902, polycrystalline emitter layer 1802b, and second dielectric spacer layer 3604a may result in residual portions of those layers in the first transition region 106. As illustrated, a residual emitter dielectric cap spacer 1902b, a residual polycrystalline emitter spacer 1802d, and a residual second dielectric spacer 3604c remain in the first transition region 106.

Then, the first dielectric spacer layer 3602a and the base layer 1302 (e.g., the polycrystalline base layer 1302b) are patterned, and portions of the pedestal dielectric layer 202b are thinned. The first dielectric spacer layer 3602a is patterned to remain as the first dielectric spacer layer 3602b. The polycrystalline base layer 1302b is patterned to remain as the polycrystalline base layer 1302c. The pedestal dielectric layer 202b is thinned in areas where the polycrystalline base layer 1302b is removed and results in the pedestal dielectric layer 202c (similar to the pedestal dielectric layer 202c as shown in FIG. 27A). The first dielectric spacer layer 3602a, the polycrystalline base layer 1302b, and the pedestal dielectric layer 202b may be patterned or thinned using appropriate photolithography and etch (e.g., RIE) processes. Patterning the base layer 1302 (e.g., the polycrystalline base layer 1302b) as illustrated permits residual polycrystalline base spacer 1302d to remain on respective sidewalls 802, 804 in the first transition region 106. Patterning the first dielectric spacer layer 3602a as illustrated permits residual dielectric spacer 3602c to remain on the residual polycrystalline base spacer 1302d. The etch process may also etch residual spacers at the sidewalls 802, 804, which may remove the residual emitter dielectric cap spacers 1902b, as illustrated.

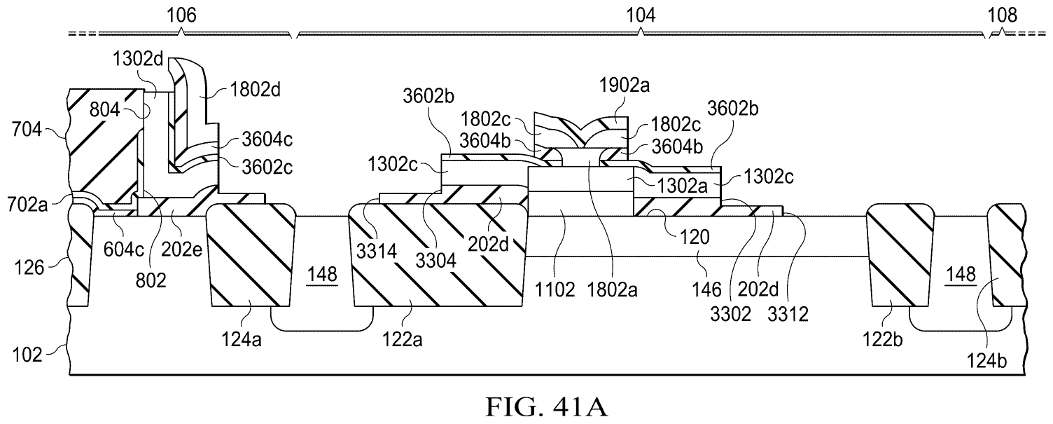

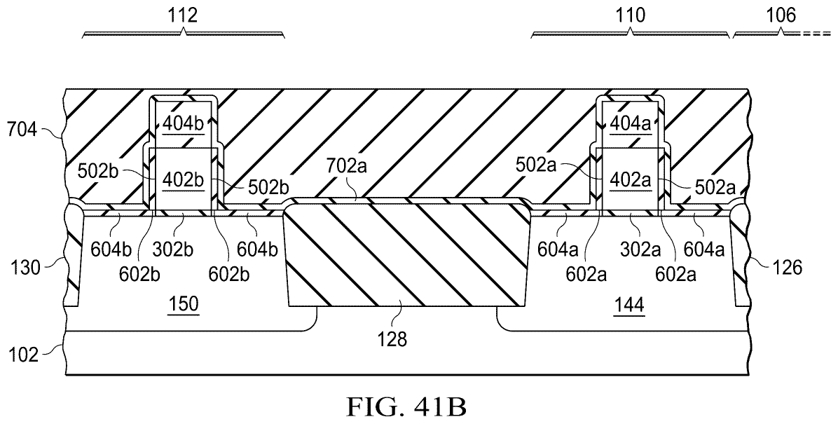

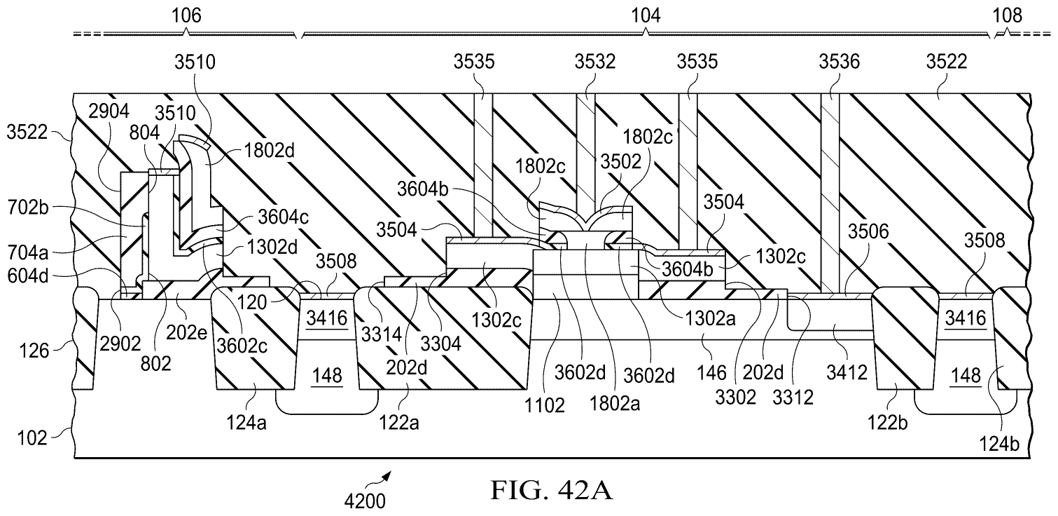

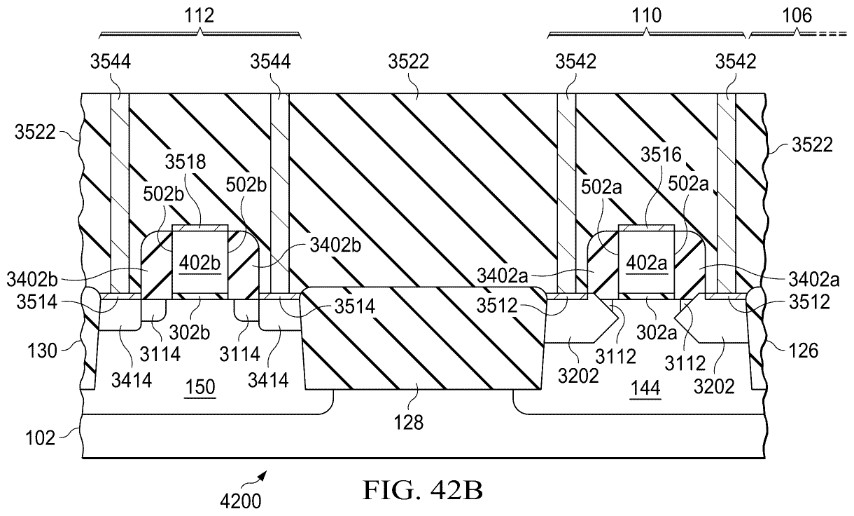

Thereafter, semiconductor processing continues as described with respect to FIGS. 28A and 28B through FIGS. 35A and 35B above. FIGS. 41A and 41B correspond with processing through the processing described with respect to FIGS. 33A and 33B. With respect to the formation of metal-semiconductor compound described above with respect to FIGS. 42A and 42B, metal-semiconductor compound 3504 is on the base layer 1302 (e.g., the polycrystalline base layer 1302c). The deposited metal is reacted with the semiconductor material of the base layer 1302 (e.g., the polycrystalline base layer 1302c). In processing to form the metal-semiconductor compound, the first dielectric spacer layer 3602b not underlying the second dielectric spacer 3604b may be removed, such as by a cleaning or etch process, which may cause a first dielectric spacer 3602d to remain under the second dielectric spacer 3604b.

FIGS. 35A and 35B illustrate a semiconductor device 3500, and FIGS. 42A and 42B illustrate a semiconductor device 4200. Each illustrated semiconductor device 3500, 4200 includes a BJT in the BJT region 104. The BJT includes the collector layer 1102, base layer 1302 (e.g., monocrystalline base layer 1302a and polycrystalline base layer 1302c), and emitter layer 1802 (e.g., monocrystalline emitter layer 1802a and polycrystalline emitter layer 1802b). The BJT of the semiconductor device 3500 of FIGS. 35A and 35B also includes a raised base layer 2502a on the base layer 1302 (e.g., on the polycrystalline base layer 1302c).

The collector layer 1102 is over and on the upper surface 120 of the semiconductor substrate 102 and is through an opening in a pedestal dielectric layer 202d, which is also over and on the upper surface of the semiconductor substrate 102. The collector layer 1102 is on the n-type doped sub-collector diffusion region 146 in the semiconductor substrate 102. The base layer 1302 (e.g., the monocrystalline base layer 1302a) is over and on the collector layer 1102, and the base layer 1302 (e.g., the polycrystalline base layer 1302c) is over and on an upper surface of the pedestal dielectric layer 202d.

The pedestal dielectric layer 202d extends laterally from the base layer 1302, such as laterally over and along the upper surface 120 of the semiconductor substrate 102 in a lateral direction from a respective sidewall of the base layer 1302 to the sidewall 3312 of the pedestal dielectric layer 202d at the n-type collector contact region 3412, which sidewall 3312 is laterally away from the sidewall 3302 of the pedestal dielectric layer 202d that is aligned with the respective sidewall of the base layer 1302. The pedestal dielectric layer 202d also extends laterally from the base layer 1302, such as laterally over and along the first portion 122a of the isolation structure 122 in a lateral direction from a respective sidewall of the base layer 1302 to the sidewall 3314 of the pedestal dielectric layer 202d over the first portion 122a of the isolation structure 122, which sidewall 3314 is laterally away from the sidewall 3304 of the pedestal dielectric layer 202d that is aligned with the respective sidewall of the base layer 1302. The pedestal dielectric layer 202d has a thickness laterally between the sidewalls 3302, 3312 and laterally between the sidewalls 3304, 3314, which is less than a thickness of the pedestal dielectric layer 202d laterally between the sidewalls 3302, 3304.

The emitter layer 1802 (e.g., the monocrystalline emitter layer 1802a) is over and on the base layer 1302 (e.g., the monocrystalline base layer 1302a) and is through an opening defined by a spacer structure, and the emitter layer 1802 (e.g., the polycrystalline emitter layer 1802c) is over and on the spacer structure. In the semiconductor device 3500 of FIGS. 35A and 35B, the spacer structure includes the second dielectric spacer 1404b, the third dielectric spacer 1406d, and emitter dielectric spacer 1602a. In the semiconductor device 4200 of FIGS. 42A and 42B, the spacer structure includes the first dielectric spacer 3602d and the second dielectric spacer 3604b.

The metal-semiconductor compound 3502 is on the emitter layer 1802 (e.g., the polycrystalline emitter layer 1802c and/or monocrystalline emitter layer 1802a). The metal-semiconductor compound 3506 is on the upper surface 120 of the semiconductor substrate 102 on the n-type collector contact region 3412. In the semiconductor device 3500 of FIGS. 35A and 35B, the metal-semiconductor compound 3504 is on the raised base layer 2502a. In the semiconductor device 4200 of FIGS. 42A and 42B, the metal-semiconductor compound 3504 is on the base layer 1302 (e.g., the polycrystalline base layer 1302c).

In some examples, the BJT may be a heterojunction BJT. As indicated previously, in some examples, the collector layer 1102 and the emitter layer 1802 may be silicon, and the base layer 1302 may include silicon germanium. Hence, in some examples, the base layer 1302 may include a semiconductor material dissimilar from respective semiconductor materials of the collector layer 1102 and emitter layer 1802. The dissimilar semiconductor materials may form one or more heterojunctions in the BJT, and the BJT may therefore be a heterojunction BJT.

Each illustrated semiconductor device 3500, 4200 includes a pFET in the pFET region 110 and an nFET in the nFET region 112. The pFET region 110 and nFET region 112 are in a CFET region. The pFET includes the gate electrode 402a, gate dielectric layer 302a, embedded stressors 3202, PSD regions, p-type LDDs 3112, and a channel region in the semiconductor substrate 102 underlying the gate electrode 402a. The gate electrode 402a is over and on the gate dielectric layer 302a, and the gate dielectric layer 302a is over and on the upper surface 120 of the semiconductor substrate 102. The p-type LDDs 3112 are on laterally opposing sides of the gate electrode 402a and in the semiconductor substrate 102. The channel region is laterally between the p-type LDDs 3112. The embedded stressors 3202 and PSD regions are on laterally opposing sides of the gate electrode 402a, with the p-type LDDs 3112 and channel region therebetween. Similarly, the nFET includes the gate electrode 402b, gate dielectric layer 302b, NSD regions 3414, n-type LDDs 3114, and a channel region in the semiconductor substrate 102 underlying the gate electrode 402b. The gate electrode 402b is over and on the gate dielectric layer 302b, and the gate dielectric layer 302b is over and on the upper surface 120 of the semiconductor substrate 102. The n-type LDDs 3114 are on laterally opposing sides of the gate electrode 402b and in the semiconductor substrate 102. The channel region is laterally between the n-type LDDs 3114. The NSD regions 3414 are on laterally opposing sides of the gate electrode 402b, with the n-type LDDs 3114 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET region having a boundary of the pFET region 110 in the illustrated examples). The second transition region 108 extends from a boundary of the BJT region 104 (e.g., opposite from the first transition region 106). A composite structure may remain in the first transition region 106 and/or second transition region 108. The composite structure may be respective residuals of various layers formed during semiconductor processing and/or may be processing artifact(s). The composite structure includes the residual fill material 704a, as shown in FIGS. 35A and 42A. The residual fill material 704a has a sidewall 2904 that faces the CFET region (e.g., the pFET region 110) and has a top surface that forms at least a portion of an upper surface of the composite structure. The composite structure also includes the etch stop layer 702b that has a sidewall 2902 that faces the CFET region. Further, the composite structure may include one or both of a residual polycrystalline base spacer 1302d and a residual polycrystalline emitter spacer 1802d. The residual polycrystalline base spacer 1302d is on sidewalls 804, 802 of the residual fill material 704a and etch stop layer 702b, respectively, that face opposite from the sidewalls 2904, 2902. The composite structure may include one or more residual dielectric spacers, such as the residual dielectric spacers 1402b, 1404c, 1406e, 1602c as shown in FIG. 35A and the residual dielectric spacers 3602c, 3604c as shown in FIG. 42A. Other composite structures may be formed.

The semiconductor processing to form the semiconductor devices 3500, 4200 of FIGS. 35A-35B and 42A-42B may enable vertical scaling and horizontal scaling. In some examples, for vertical scaling, thicknesses of the collector layer 1102, base layer 1302, and emitter layer 1802 may be reduced. In some examples, a thickness of the collector layer 1102 does not exceed 200 nm, and a thickness of the base layer 1302 (e.g., the monocrystalline base layer 1302a) does not exceed 100 nm. Further, in some examples, the thickness of the collector layer 1102 is in a range from 10 nm to 100 nm, and a thickness of the base layer 1302 (e.g., the monocrystalline base layer 1302a) is in a range from 10 nm to 50 nm. Additionally, in some examples, a thickness of the emitter layer 1802 (e.g., the monocrystalline emitter layer 1802a) does not exceed 100 nm. In some examples, the thickness of the emitter layer 1802 (e.g., the monocrystalline emitter layer 1802a) is in a range from 10 nm to 50 nm. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner.

For horizontal scaling, widths of respective openings in which the collector layer 1102 and the emitter layer 1802 (e.g., the monocrystalline emitter layer 1802a) are formed, may be reduced. The width of the collector opening 1002, in which the collector layer 1102 is formed, may be reduced, and the width of the emitter opening 1702, 3702, in which the monocrystalline emitter layer 1802a is formed, may be reduced. The semiconductor processing described above may enable horizontal scaling to, e.g., a 28 nm technology node and beyond (e.g., a 21 nm technology node or less). Referring to FIG. 43, the lateral boundaries of the pedestal dielectric layer 202d are shown. The collector layer 1102 is laterally interior within the pedestal dielectric layer 202d in the collector opening 1002. The collector opening 1002 and hence, the collector layer 1102, has a width 4312. The lateral boundaries of the base layer 1302 (e.g., the polycrystalline base layer 1302c), and where applicable, the raised base layer 2502a, are also shown. The emitter opening 1702, 3702 shown in FIGS. 17A and 37A are shown. The emitter opening 1702, 3702 has a width 4314. The emitter layer 1802 (e.g., the monocrystalline emitter layer 1802a) is formed in the emitter opening 1702, 3702. One or both of the widths 4312, 4314 may be reduced for horizontal scaling. In some examples, the width 4312 does not exceed 200 nm, and the width 4314 does not exceed 120 nm. Further, in some examples, the width 4312 is in a range from 80 nm to 180 nm, and the width 4314 is in a range from 40 nm to 100 nm.

Although various examples have been described in detail, it should be understood that various changes, substitutions, and alterations can be made therein without departing from the scope defined by the appended claims.

What is claimed is:

1. A semiconductor device, comprising:
a semiconductor substrate including a bipolar junction transistor (BJT) region, a complementary field effect transistor (CFET) region, and a transition region between the BJT region and the CFET region;
a BJT on the semiconductor substrate in the BJT region;
a field effect transistor (FET) on the semiconductor substrate in the CFET region; and
a composite structure on the semiconductor substrate in the transition region, the composite structure comprising a dielectric material, the dielectric material having a first sidewall proximate and facing the CFET region and having a top surface that forms at least a portion of an upper surface of the composite structure.

2. The semiconductor device of claim 1, wherein:
the BJT comprises:
a collector layer on the semiconductor substrate;
a base layer on the collector layer; and
an emitter layer on the base layer; and
the composite structure further comprises a semiconductor material that is the same as the base layer.

3. The semiconductor device of claim 2, wherein the semiconductor material is on a second sidewall of the dielectric material, the second sidewall facing opposite from the first sidewall.

4. The semiconductor device of claim 1, further comprising a pedestal dielectric layer on the semiconductor substrate in the BJT region, wherein the BJT comprises:
a collector layer in an opening through the pedestal dielectric layer;
a base layer on the collector layer and the pedestal dielectric layer; and
an emitter layer on the base layer.

5. The semiconductor device of claim 4, wherein the semiconductor substrate includes:
a doped sub-collector diffusion region in the BJT region, the collector layer being on the doped sub-collector diffusion region; and
a doped collector contact region in the doped sub-collector diffusion region, at least a portion of the pedestal dielectric layer being laterally between the collector layer and the doped collector contact region.

6. The semiconductor device of claim 4, wherein the pedestal dielectric layer extends laterally away from the base layer.

7. The semiconductor device of claim 4, wherein the BJT further comprises a raised base layer on the base layer.

8. The semiconductor device of claim 7, further comprising:
a base metal-semiconductor compound on the raised base layer; and
an emitter metal-semiconductor compound on the emitter layer.

9. The semiconductor device of claim 4, further comprising:
a base metal-semiconductor compound on the base layer; and
an emitter metal-semiconductor compound on the emitter layer.

10. A method, comprising:
forming a gate layer over a semiconductor substrate in a bipolar junction transistor (BJT) region, a transition region, and a complementary field effect transistor (CFET) region, the transition region being between the BJT region and the CFET region;
patterning the gate layer into a gate electrode of a field effect transistor (FET) in the CFET region;
after patterning the gate layer into the gate electrode, forming a collector layer on an upper surface of the semiconductor substrate in the BJT region;
forming a base layer on the collector layer; and
forming an emitter layer on the base layer.

11. The method of claim 10, further comprising oxidizing a sidewall of the gate electrode before forming the collector layer.

12. The method of claim 10, further comprising forming a fill material on a lateral side of the gate electrode.

13. The method of claim 12, further comprising removing at least a portion of the gate layer from the BJT region, the collector layer being formed where the portion of the gate layer was removed.

14. The method of claim 13, wherein removing the portion of the gate layer from the BJT region forms an opening at least in the BJT region defined, at least in part, by a sidewall of the fill material.

15. The method of claim 14, wherein the collector layer, the base layer, and the emitter layer are formed in the opening.

16. The method of claim 12, further comprising planarizing the fill material before forming the collector layer.

17. The method of claim 12, further comprising removing the fill material from the lateral side of the gate electrode after forming the emitter layer, wherein at least a portion of the fill material remains in the transition region after removing the fill material from the lateral side of the gate electrode.

18. The method of claim 17, wherein forming the base layer includes:
depositing a material of the base layer; and
etching the material of the base layer into the base layer, wherein a portion of the material of the base layer remains on a sidewall of the fill material after etching the material of the base layer and after removing the fill material from the lateral side of the gate electrode.

19. A method, comprising:
forming a gate layer over a semiconductor substrate in a bipolar junction transistor (BJT) region and a complementary field effect transistor (CFET) region;
patterning the gate layer in the CFET region into a gate electrode of a field effect transistor (FET) in the CFET region;
forming a fill material in the CFET region along a side of the gate electrode;
forming a collector layer on the semiconductor substrate and in the BJT region;
forming a material of a base layer over the collector layer and over the fill material;
forming a material of an emitter layer over the base layer;
patterning the material of the emitter layer into the emitter layer in the BJT region; and
patterning the material of the base layer into the base layer in the BJT region.

20. The method of claim 19, further comprising oxidizing a sidewall of the gate electrode before forming the fill material, the fill material being formed on the oxidized sidewall of the gate electrode.

21. The method of claim 19, further comprising, after forming the fill material in the CFET region, removing at least a portion of the gate layer from the BJT region, the collector layer being formed where the portion of the gate layer was removed.

22. The method of claim 21, wherein removing the portion of the gate layer from the BJT region forms an opening at least in the BJT region defined, at least in part, by a sidewall of the fill material.

23. The method of claim 19, further comprising planarizing the fill material before forming the collector layer.

24. The method of claim 19, further comprising removing the fill material from the side of the gate electrode after patterning the base layer, wherein at least a portion of the fill material remains in a transition region after removing the fill material from the side of the gate electrode, the transition region being between the CFET region and the BJT region.

25. The method of claim 24, wherein a portion of the material of the base layer remains on a sidewall of the fill material after patterning the base layer and after removing the fill material from the side of the gate electrode.
